(19) United States
(12) Patent Application Publication
(10) Pub. No.: US 2025/0169057 A1
(43) Pub. Date: May 22, 2025

(54) SEMICONDUCTOR MEMORY DEVICE

(71) Applicant: Samsung Electronics Co., Ltd., Suwon-si (KR)

(72) Inventors: Dokeun LEE, Suwon-si (KR); Yangdoo KIM, Suwon-si (KR); Sang Wuk PARK, Suwon-si (KR); Minkyu SUH, Suwon-si (KR); Geonyeop LEE, Suwon-si (KR); Jihye LEE, Suwon-si (KR); Jungpyo HONG, Suwon-si (KR)

(21) Appl. No.: 18/745,013

(22) Filed: Jun. 17, 2024

(30) Foreign Application Priority Data
Nov. 21, 2023 (KR) 10-2023-0161989

(51) Int. Cl. H10B 12/00

(52) U.S. Cl. CPC H10B 12/315; H10B 12/033

(57) ABSTRACT

A semiconductor memory device includes a conductive pattern on a substrate, a lower electrode connected to the conductive pattern and including first and second portions, one or more electrode side wall supports supporting the lower electrode and contacting a side wall of the lower electrode, an electrode capping support disposed on the lower electrode and contacting an upper face of the lower electrode, a capacitor dielectric film on the lower electrode, the electrode side wall supports, and the electrode capping support, and an upper electrode on the capacitor dielectric film. The first portion of the lower electrode has an increasing width in the first d in a second direction increases as it goes away from the conductive pattern, and a slope of the side wall of the first portion of the lower electrode is different from a slope of the side wall of the second portion of the lower electrode.

### CROSS-REFERENCE TO RELATED APPLICATION

This application claims priority from Korean Patent Application No. 10-2023-0161989 filed on Nov. 21, 2023 in the Korean Intellectual Property Office, and all the benefits accruing therefrom under 35 U.S.C. 119, the contents of which in its entirety are herein incorporated by reference.

### BACKGROUND

### Field of the Disclosure

The present disclosure relates to a semiconductor memory device, and more specifically, to a semiconductor memory device that uses a capacitor as a data storage element.

### Description of the Related Art

In recent years, as semiconductor memories have become a larger capacity and more highly integrated, design rules have also been continuously reduced. Such a trend is also appearing in a dynamic random access memory (DRAM), which is one of memory semiconductor memories. For a DRAM device to operate, each cell is desirable to have capacitance of a certain level or more.

The increase in capacitance may lead to a greater accumulation of charges within the capacitor, thereby improving the refresh characteristics of the semiconductor device. This enhancement of refresh characteristics of the semiconductor device may improve the yield of the semiconductor device.

Efforts to increase the capacitance involve employing a dielectric film having a high dielectric constant in capacitors or increasing a contact area between a lower electrode of a capacitor and a dielectric film.

### SUMMARY

Aspects of the present disclosure provide a semiconductor memory device including a capacitor that may increase capacitance.

According to an aspect of the present disclosure, there is provided a semiconductor memory device comprising a conductive pattern on a substrate, a lower electrode which is connected to the conductive pattern, extends in a first direction, and includes a first portion and a second portion, the first portion of the lower electrode being disposed between the conductive pattern and the second portion of the lower electrode, one or more electrode side wall supports that support the lower electrode and are in contact with a side wall of the lower electrode, an electrode capping support which is disposed on the lower electrode, and is in contact with an upper face of the lower electrode, a capacitor dielectric film on the lower electrode, the electrode side wall support, and the electrode capping support and an upper electrode on the capacitor dielectric film, wherein the first portion of the lower electrode has an increasing width in the first direction away from the conductive pattern, and a slope of the side wall of the first portion of the lower electrode is different from a slope of the side wall of the second portion of the lower electrode.

According to an aspect of the present disclosure, there is provided a semiconductor memory device comprising a conductive pattern on a substrate, a lower electrode which is connected to the conductive pattern, extends in a first direction, and includes a first portion and a second portion, the first portion of the lower electrode being disposed between the conductive pattern and the second portion of the lower electrode, a plurality of electrode side wall supports that support the lower electrode and are in contact with a side wall of the lower electrode, a capacitor dielectric film on the lower electrode and each of the electrode side wall supports, and an upper electrode on the capacitor dielectric film, wherein the first portion of the lower electrode has an increasing width in the first direction away from the conductive pattern, a slope of the side wall of the first portion of the lower electrode is different from a slope of the side wall of the second portion of the lower electrode, the electrode side wall supports include an uppermost electrode side wall support that is farthest away from the conductive pattern, the uppermost electrode side wall support includes a bottom surface that is adjacent to the conductive pattern and an upper surface opposite to the bottom surface of the uppermost electrode side wall support, and a part of the first portion of the lower electrode protrudes in the first direction beyond the upper surface of the uppermost electrode side wall support.

According to as aspect of the present disclosure, there is provided a semiconductor memory device comprising a substrate which includes an active region defined by an element separation film and extending in a first direction, the active region including a first portion and a pair of second portions disposed on opposite sides of the first portion, a word line which extends in a second direction different from the first direction and is buried in the substrate and the element separation film, and is disposed between the first portion of the active region and one of the pair of second portions of the active region, a bit line contact connected to the first portion of the active region, a bit line which is connected to the bit line contact and extends in a third direction different from the first direction and the second direction and is disposed on the bit line contact, a landing pad connected to the second portion of the active region, and a capacitor connected to the landing pad and disposed on the landing pad, wherein the capacitor includes a lower electrode connected to the landing pad and extending in the third direction, a plurality of electrode side wall supports which support the lower electrode and are in contact with a side wall of the lower electrode, an electrode capping support which is disposed on the lower electrode and is in contact with an upper face of the lower electrode, a capacitor dielectric film on the lower electrode, each of the plurality of electrode side wall supports, and the electrode capping support, and an upper electrode on the capacitor dielectric film, wherein the lower electrode includes a first portion of the lower electrode and a second portion of the lower electrode, the first portion of the lower electrode has an increasing width in the third direction=away from the landing pad, the electrode capping support is in contact with the second portion of the lower electrode, and a slope of the side wall of the first portion of the lower electrode is different from a slope of the side wall of the second portion of the lower electrode.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

FIG. 1 is an example diagram for explaining a semiconductor memory device according to some embodiments.

FIG. 2 is an enlarged view of a portion P of FIG. 1.

FIGS. 3 to 8 are diagrams for explaining a semiconductor memory device according to some embodiments, respectively.

FIGS. 9 and 10 are diagrams for explaining a semiconductor memory device according to some embodiments.

FIG. 11 is a layout diagram of a semiconductor memory device according to some embodiments.

FIG. 12 is a layout showing a word line and a cell active region film of FIG. 11.

FIG. 13 is a cross-sectional view taken along a line A-A of FIG. 11.

FIGS. 14 and 15 are diagrams for explaining a semiconductor memory device according to some embodiments.

FIG. 16 is a layout diagram for explaining a semiconductor memory device according to some embodiments.

FIG. 17 is a perspective view for explaining the semiconductor memory device according to some embodiments.

FIG. 18 is a cross-sectional view taken along lines B-B and C-C of FIG. 16.

FIG. 19 is a layout diagram for explaining a semiconductor memory device according to some embodiments.

FIG. 20 is a perspective view for explaining a semiconductor memory device according to some embodiments.

FIG. 21 is a diagram for explaining a semiconductor memory device according to some embodiments.

FIGS. 22 to 33 are intermediate step diagrams for explaining a method for fabricating a semiconductor memory device according to some embodiments.

### DETAILED DESCRIPTION OF THE EMBODIMENTS

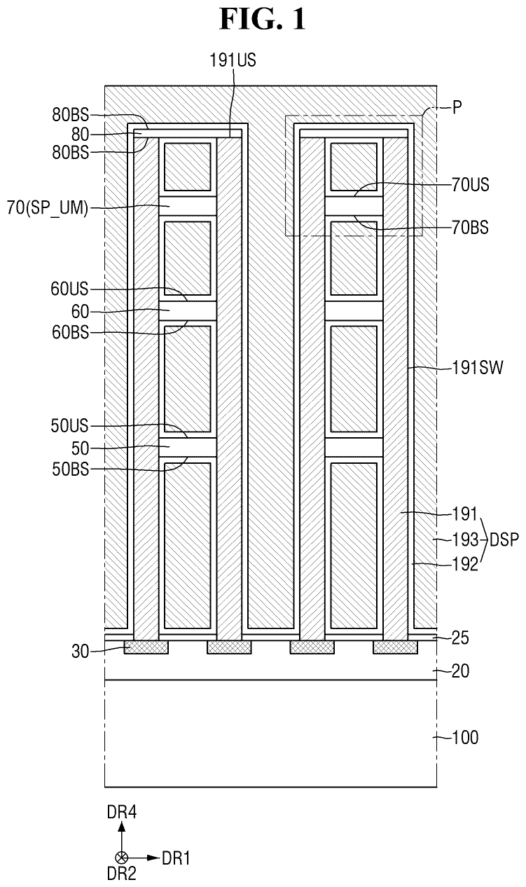

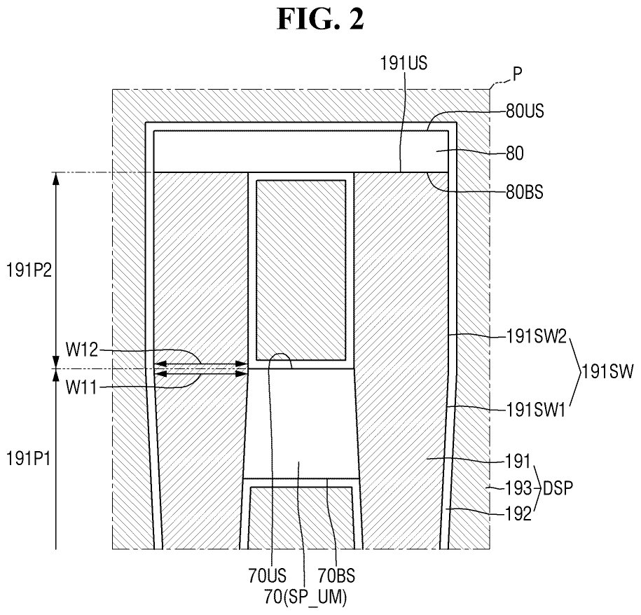

A semiconductor memory device according to some embodiments will be described with reference to FIGS. 1 and 2.

FIG. 1 is an example diagram for explaining a semiconductor memory device according to some embodiments. FIG. 2 is an enlarged view of a portion P of FIG. 1.

Referring to FIGS. 1 and 2, the semiconductor memory device according to some embodiments may include a conductive pattern 30, a lower electrode 191, a capacitor dielectric film 192, an upper electrode 193, at least one or more electrode side wall supports 50, 60 and 70, and an electrode capping support 80.

The conductive pattern 30 may be disposed on the substrate 100. Although the conductive pattern 30 is shown as being separated from the substrate 100, this is only for convenience of explanation and is not limited thereto. In some embodiments, the conductive pattern 30 may be electrically connected to a conductive region formed on or in the substrate 100.

An interlayer insulating film 20 may be disposed on the substrate 100. The conductive pattern 30 may be disposed in the interlayer insulating film 20.

The substrate 100 may be bulk silicon or silicon-on-insulator (SOI). In some embodiments, the substrate 100 may be a silicon substrate, or may include other materials, for example, but not limited to, silicon germanium, SGOI (silicon germanium on insulator), indium antimonide, lead telluride, indium arsenide, indium phosphide, gallium arsenide or gallium antimonide. In the following description, the substrate 100 is described as being a silicon substrate.

The interlayer insulating film 20 may include or may be, for example, at least one of a silicon oxide film, a silicon nitride film, a silicon oxynitride film (SiON), a silicon oxycarbonitride film (SiOCN), a silicon carbonitride film (SiCN), a combination thereof.

The conductive pattern 30 may include or may be formed of a conductive material. The conductive pattern 30 may include or may be formed of, for example, at least one of a doped semiconductor material, a conductive metal nitride, a conductive metal silicon nitride, a metal carbonitride, a conductive metal silicide, a conductive metal oxide, a two-dimensional material (2D material), and a metal. In the semiconductor memory device according to some embodiments, the 2D material may be a metallic material and/or a semiconductor material. The 2D material may include a 2D allotrope or a 2D compound, and may include, but not limited to, at least one of graphene, molybdenum disulfide (MoS₂), molybdenum diselenide (MoSe₂), tungsten diselenide (WSe₂), and tungsten disulfide (WS₂). The above-mentioned 2D materials are only listed by way of example. The 2D materials that may be included in the semiconductor device of the present disclosure are not limited by the above-mentioned materials. Although a peri-gate structure PG is shown to include a plurality of conductive patterns, the embodiment is not limited thereto.

A first etching stop film 25 may be disposed on the interlayer insulating film 20. The first etching stop film 25 may expose at least a part of the conductive pattern 30.

As an example, the first etching stop film 25 may be disposed on the conductive pattern 30. The first etching stop film 25 may include a lower electrode hole that exposes at least a part of the conductive pattern 30.

The first etching stop film 130 may include or may be formed of, for example, at least one of a silicon nitride film, a silicon carbonitride film, a silicon boron nitride film (SiBN), a silicon carbonate film (SiCO), a silicon oxynitride film, and a silicon oxycarbonitride film. For example, the silicon carbonate film (SiCO) contains silicon (Si), carbon (C) and oxygen (O), but does not mean a ratio of silicon (Si), carbon (C) and oxygen (O).

A data storage pattern DSP may be disposed on the conductive pattern 30. The data storage pattern DSP may be electrically connected to the conductive pattern 30.

As an example, the data storage patterns DSP may be capacitors. The data storage pattern DSP may include a lower electrode 191, a capacitor dielectric film 192, and an upper electrode 193.

A plurality of lower electrodes 191 may be disposed on the conductive pattern 30. The lower electrode 191 may be connected to the conductive pattern 30. A part of the lower electrode 191 may be disposed in the first etching stop film 25.

For example, each lower electrode 191 may have a pillar shape. The lower electrode 191 may extend long in a fourth direction DR4, which is a thickness direction of the substrate 100. A length of the lower electrode 191 extending in the fourth direction DR4 is greater than a length of the lower electrode 191 extending in directions DR1 and DR2 parallel to the substrate 100. The shape of the lower electrode 191 will be described below.

For example, the plurality of lower electrodes 191 may be repeatedly aligned along the first direction DR1. Although not shown, the lower electrodes 191 may be repeatedly aligned in the second direction DR2. The first direction DR1 and the second direction DR2 may be orthogonal to each other, but are not limited thereto. The first direction DR1 and the second direction DR2 may be a direction parallel to an upper surface of the substrate 100, or may be orthogonal to the fourth direction DR4 which is perpendicular to the upper surface of the substrate 100.

The lower electrode 191 may be include or may be formed of, for example, a doped semiconductor material, a conductive metal nitride (e.g., titanium nitride, tantalum nitride, niobium nitride or tungsten nitride), a metal (e.g., ruthenium, iridium, titanium or tantalum), a conductive metal oxide (e.g., iridium oxide or niobium oxide), or the like. In the semiconductor memory device according to some embodiments, the lower electrode 191 may include or may be formed of titanium nitride (TiN). In the semiconductor memory device according to some embodiments, the lower electrode 191 may include or may be formed of niobium nitride (NbN).

At least one or more electrode side wall supports 50, 60 and 70 may be disposed on the first etching stop film 25. Each of the electrode side wall supports 50, 60 and 70 may support the lower electrode 191. In an embodiment, each of the electrode side wall supports 50, 60 and 70 may horizontally support the lower electrode 191. For example, the electrode side wall supports 50, 60, and 70 may be disposed in a space between two adjacent lower electrodes 191 which are spaced apart from each other in the first direction DR1. The electrode side wall supports 50, 60, and 70 may contact facing side walls of the two adjacent lower electrodes 191, thereby supporting each of the two adjacent lower electrodes 191.

For example, a plurality of electrode side wall supports 50, 60, and 70 may be disposed on the first etching stop film 25. The plurality of electrode side wall supports 50, 60, and 70 may include a first electrode side wall support 50, a second electrode side wall support 60, and a third electrode side wall support 70 that are sequentially disposed on the first etching stop film 25.

The first electrode side wall support 50, the second electrode side wall support 60, and the third electrode side wall support 70 may be spaced apart from the first etching stop film 25 in the fourth direction DR4. The first electrode side wall support 50, the second electrode side wall support 60, and the third electrode side wall support 70 may be spaced apart from each other in the fourth direction DR4.

The electrode side wall supports 50, 60 and 70 may include an uppermost electrode side wall support SP_UM. The uppermost electrode side wall support SP_UM may be an electrode side wall support that is farthest from the conductive pattern 30 in the fourth direction DR4 among the electrode side wall supports 50, 60, and 70. For example, the third electrode side wall support 70 may be the uppermost electrode side wall support SP_UM. The first electrode side wall support 50 may be the electrode side wall support that is closest to the conductive pattern 30 in the fourth direction DR4.

The first electrode side wall support 50, the second electrode side wall support 60, and the third electrode side wall support 70 may each be in contact with the lower electrode 191. The first electrode side wall support 50, the second electrode side wall support 60, and the third electrode side wall support 70 may each be in contact with a part of a side wall 191SW of the lower electrode.

Although the number of electrode side wall supports being in contact with the side wall 191SW of the lower electrode is shown as three, the technical idea of the present disclosure is not limited thereto. Single electrode side wall support may contact the side wall 191SW of the lower electrode 191, or more than three electrode side wall supports may contact the side wall 191SW of the lower electrode 191.

The first electrode side wall support 50 may include an upper face 50US (i.e., an upper surface) and a bottom face 50BS (“i.e., a lower surface”) that are opposite to each other in the fourth direction DR4. The second electrode side wall support 60 may include an upper face 60US and a bottom face 60BS that are opposite to each other in the fourth direction DR4. The third electrode side wall support 70 may include an upper face 70US and a bottom face 70BS that are opposite to each other in the fourth direction DR4. The bottom face 50BS of the first electrode side wall support, the bottom face 60BS of the second electrode side wall support, and the bottom face 70BS of the third electrode side wall support may look at the conductive pattern 30, respectively.

Each lower electrode 191 protrudes in the fourth direction DR4 beyond the third electrode side wall support 70, which is the uppermost electrode side wall support SP_UM. A part of the lower electrode 191 protrudes in the fourth direction DR4 beyond the upper face 70US of the third electrode side wall support. For example, an upper surface of each lower electrode 191 may be higher than the upper surface of the uppermost electrode side wall support SP_UM.

Each of the first electrode side wall support 50, the second electrode side wall support 60, and the third electrode side wall support 70 may include or may be formed of an insulating material. For example, each of the first to third electrode side wall support 50, 60, and 70 may include or may be formed of, for example, at least one of silicon nitride, silicon carbonitride, silicon boron nitride, silicon carbonate, silicon oxynitride, and silicon oxycarbonitride. In an embodiment, a thickness of the third electrode side wall support 70 in the fourth direction DR4 may be the same as a thickness of each of the first electrode side wall support 50 and the second electrode side wall support 60. The embodiment is not limited thereto. In an embodiment, the thickness of the third electrode side wall support 70 in the fourth direction DR4 may be different from the thickness of the first electrode side wall support 50. In an embodiment, the thickness of the third electrode side wall support 70 may be different from the thickness of the second electrode side wall support 60.

The electrode capping support 80 may be disposed on the lower electrode 191. The electrode capping support 80 may be in contact with lower electrode 191. The electrode capping support 80 may be in contact with the upper face 191US of the lower electrode. The electrode capping support 80 may support the lower electrode 191.

The electrode capping support 80 may be disposed on the third electrode side wall support 70. The electrode capping support 80 is spaced apart from the uppermost electrode side wall support SP_UM in the fourth direction DR4.

The electrode capping support 80 may include an upper face 80US and a bottom face 80BS that are opposite to each other in the fourth direction DR4. The bottom face 80BS of the electrode capping support may look at the conductive pattern 30. The bottom face 80BS of the electrode capping support may look at the upper face 70US of the third electrode side wall support.

The electrode capping support 80 may include or may be formed of, for example, at least one of silicon nitride, silicon carbonitride, silicon boron nitride, silicon carbonate, silicon oxynitride, and silicon oxycarbonitride. In an embodiment, the electrode capping support 80 may include or may be formed of the same material as the electrode side wall supports 50, 60 and 70. In an embodiment, the electrode capping support 80 may include or may be formed of a material different from the electrode side wall supports 50, 60 and 70.

The lower electrode 191 may include a first portion 191P1 and a second portion 191P2. The first portion 191P1 of the lower electrode may be disposed between the conductive pattern 30 and the second portion 191P2 of the lower electrode.

The first portion 191P1 of the lower electrode may be in contact with the conductive pattern 30. From a cross-sectional point of view, in the first portion 191P1 of the lower electrode, the width of the lower electrode 191 in the first direction DR1 may increase as it goes away from the conductive pattern 30. For example, the first portion 191P of the lower electrode may have an increasing width in the fourth direction DR4 away from the conductive pattern 30. In an embodiment, an upper surface of the conductive pattern 30 may be coplanar with or may be parallel to the upper surface of the substrate 100. In an embodiment, in the first portion 191P1 of the lower electrode, the width of the lower electrode 191 in the first direction DR1 may increase as it goes away from the conductive pattern 30. For example, the first portion 191P of the lower electrode may have an increasing width in the fourth direction DR4 away from the conductive pattern 30, and the width of the first portion 191P may be measured in the first direction DR1.

The second portion 191P2 of the lower electrode may be in contact with the electrode capping support 80. The second portion 191P2 of the lower electrode includes the upper face 191US of the lower electrode.

The side wall 191SW of the lower electrode may include a side wall 191SW1 of the first portion 191P1 of the lower electrode and a side wall 191SW2 of the second portion 191P2 of the lower electrode. For example, a slope of the side wall 191SW1 of the first portion of the lower electrode may be different from a slope of the side wall 191SW2 of the second portion of the lower electrode.

The slope of the side wall 191SW2 of the second portion of the lower electrode may be greater than the slope of the side wall 191SW1 of the first portion of the lower electrode. In other words, the inclination of the side wall 191SW2 of the second portion of the lower electrode may be steeper than the inclination of the side wall 191SW1 of the first portion of the lower electrode.

In an embodiment, the slope of the side wall 191SW2 of the second portion of the lower electrode may be smaller than the slope of the side wall 191SW1 of the first portion of the lower electrode.

In the semiconductor memory device according to some embodiments, the first portion of the lower electrode 191P1 may be in contact with the second portion of the lower electrode 191P2. The first portion 191P1 of the lower electrode may be directly connected to the second portion 191P2 of the lower electrode.

For example, a width W11 of the uppermost part of the lower electrode 191 in the first portion 191P1 of the lower electrode may be equal to a width W12 of the lowermost part of the lower electrode in the second portion 191P2 of the lower electrode. In an embodiment, an upper surface of the first portion 191P1 may contact a lower surface of the second portion 191P2, and the width W11 of the upper surface of the first portion 191P may be equal to the width W12 of the lower surface of the second portion 191P2.

In the semiconductor memory device according to some embodiments, a boundary between the first portion 191P1 of the lower electrode and the second portion 191P2 of the lower electrode may be located at the same level as (i.e., may be coplanar with) the upper face 70US of the third electrode side wall support. In other words, the boundary between the first portion 191P1 of the lower electrode and the second portion 191P2 of the lower electrode may be disposed at the same level as (i.e., may be coplanar with) the upper face of the uppermost electrode side wall support SP_UM.

The first portion 191P1 of the lower electrode may not protrude in the fourth direction DR4 beyond the upper face 70US of the third electrode side wall support. The second portion 191P2 of the lower electrode may protrude in the fourth direction DR4 beyond the upper face 70US of the third electrode side wall support.

The side wall 191SW1 of the first portion of the lower electrode may be in contact with the third electrode side wall support 70. The side wall 191SW2 of the second portion of the lower electrode may not be in contact with the third electrode side wall support 70. For example, the entirety of a side wall of the third electrode side wall support 70 may contact the side wall 191SW1 of the first portion of the lower electrode, without contacting the side wall 191SW2 of the second portion of the lower electrode. Since the third electrode side wall support 70 may be the uppermost electrode side wall support SP_UM, the first to third electrode side wall supports 50, 60 and 70 may be in contact with the side wall 191SW1 of the first portion of the lower electrode. The first to third electrode side wall supports 50, 60, and 70 may not be in contact with the side wall 191SW2 of the second portion of the lower electrode. For example, the entirety of a side wall of each of the first to third electrode side wall supports 50, 60, and 70 may contact the side wall 191SW1 of the first portion of the lower electrode, without contacting the side wall 191SW2 of the second portion of the lower electrode.

In the semiconductor memory device according to some embodiments, the electrode capping support 80 may not be in contact with the side wall 191SW of the lower electrode. The electrode capping support 80 may be in contact with the side wall 191SW2 of the second portion of the lower electrode. For example, a side wall of the electrode capping support 80 may be connected to the side wall 191SW2 of the second portion of the lower electrode. The bottom face 80BS of the electrode capping support may be disposed at the same plane as (i.e., may be coplanar with) the upper face 191US of the lower electrode.

A capacitor dielectric film 192 may be disposed on the lower electrode 191. The capacitor dielectric film 192 may be disposed on the electrode side wall supports 50, 60 and 70 and the electrode capping support 80.

The capacitor dielectric film 192 may extend along the side wall 191SW of the lower electrode, the upper face 80US of the electrode capping support, and the bottom face 80BS of the electrode capping support. Since the upper face 191US of the lower electrode is in contact with the electrode capping support 80, the capacitor dielectric film 192 is not disposed between the upper face 191US of the lower electrode and the bottom face 80BS of the electrode capping support.

The capacitor dielectric film 192 may extend along the upper face 50US of the first electrode side wall support, the bottom face 50BS of the first electrode side wall support, the upper face 60US of the second electrode side wall support, the bottom face 60BS of the second electrode side wall support, the upper face 70US of the third electrode side wall support, and the bottom face 70BS of the third electrode side wall support.

For example, the capacitor dielectric film 192 may include or may be formed of, for example, but not limited to, silicon oxide, silicon nitride, silicon oxynitride, hafnium oxide, hafnium silicon oxide, hafnium zirconium oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, lead zirconium titanium oxide, yttrium oxide, aluminum oxide, lead scandium tantalum oxide, lead zinc niobate, or a combination thereof.

In an embodiment, the capacitor dielectric film 192 may include or may be formed of a stacked film structure in which zirconium oxide, aluminum oxide, and zirconium oxide are sequentially stacked. In an embodiment, the capacitor dielectric film 192 may include or may be formed of a dielectric film that includes hafnium (Hf). The content of the material of the capacitor dielectric film 192 described above is merely an example, and the technical idea of the present disclosure is not limited thereto.

The capacitor dielectric film 192 may include or may be formed of at least one of a ferroelectric material, an antiferroelectric material, and a paraelectric material. For example, the capacitor dielectric film 192 may include or may be formed of at least one of the ferroelectric material, the antiferroelectric material, the paraelectric material, a combination of the ferroelectric material and the antiferroelectric material, a combination of the ferroelectric material and the paraelectric material, a combination of the paraelectric material and the antiferroelectric material, and a combination of the ferroelectric material, the antiferroelectric material and the paraelectric material.

In an embodiment, the data storage patterns DSP may be variable resistance patterns that may be switched between two resistance states by electrical pulses applied to the memory elements. For example, the data storage patterns DSP may include a phase-change material, perovskite compounds, transition metal oxide, magnetic materials, ferromagnetic materials or antiferromagnetic materials in which a crystalline state changes depending on the amount of current.

The upper electrode 193 may be disposed on the capacitor dielectric film 192. The upper electrode 193 may fill the space between adjacent lower electrodes 191. The upper electrode 193 may fill the space between the electrode capping support 80 and the third electrode side wall support 70 and between the electrode side wall support 50, 60, and 70 adjacent in the fourth direction DR4. The upper electrode 193 may fill the space between the first electrode side wall support 50 and the interlayer insulating film 20.

The upper electrode 193 may include or may be formed of, for example, but not limited to, a doped semiconductor material, a conductive metal nitride (e.g., titanium nitride, tantalum nitride, niobium nitride or tungsten nitride, etc.), a metal (e.g., ruthenium, iridium, titanium or tantalum, etc.), a conductive metal oxide (e.g., iridium oxide or niobium oxide), or the like.

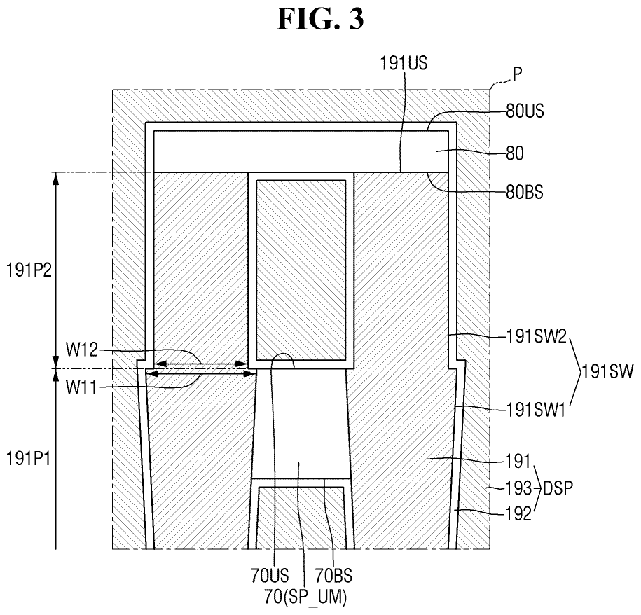

FIGS. 3 to 8 are diagrams for explaining a semiconductor memory device according to some embodiments, respectively. For convenience of explanation, the explanation will focus on the points that are different from those explained using FIGS. 1 and 2.

For reference, FIGS. 3 to 8 are enlarged views of a portion P of FIG. 1, respectively.

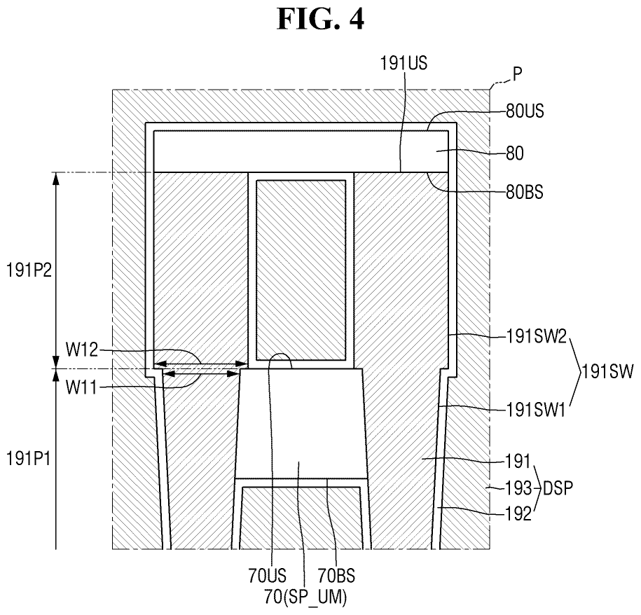

Referring to FIGS. 3 and 4, in the semiconductor memory device according to some embodiments, the width W11 of the uppermost part of the lower electrode 191 in the first portion 191P1 of the lower electrode may be different from the width W12 of the lowermost part of the lower electrode in the second portion 191P2 of the lower electrode. For example, the width W11 of an upper surface of the first portion 191P of the lower electrode may be different from the width W12 of a lower surface of the second portion 192P of the lower electrode.

In FIG. 3, the width W11 of the uppermost part of the lower electrode 191 in the first portion 191P1 of the lower electrode may be greater than the width W12 of the lowermost part of the lower electrode in the second portion 191P2 of the lower electrode. For example, the width W11 of an upper surface of the first portion 191P of the lower electrode may be greater than the width W12 of a lower surface of the second portion 192P of the lower electrode.

In FIG. 4, the width W11 of the uppermost part of the lower electrode 191 in the first portion 191P1 of the lower electrode may be smaller than the width W12 of the lowermost part of the lower electrode in the second portion 191P2. For example, the width W11 of an upper surface of the first portion 191P of the lower electrode may be smaller than the width W12 of a lower surface of the second portion 192P of the lower electrode. A part of the second portion 191P2 of the lower electrode may be disposed over the upper face 70US of the third electrode side wall support. The second portion 191P2 of the lower electrode may be in contact with the upper face 70US of the third electrode side wall support.

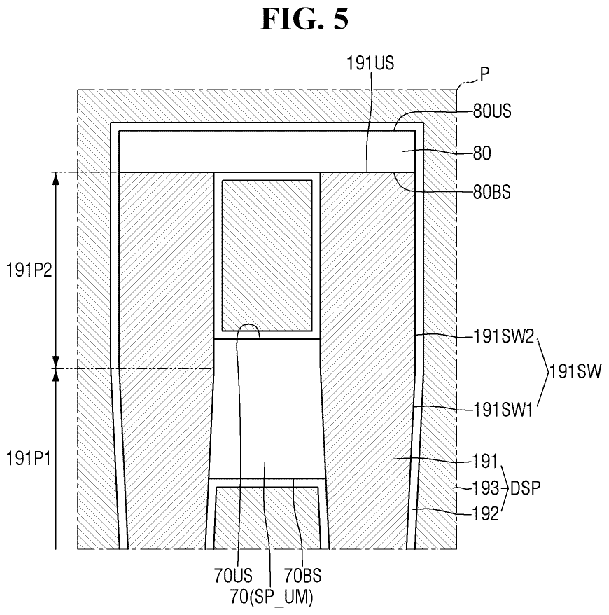

Referring to FIG. 5, in the semiconductor memory device according to some embodiments, a boundary between the first portion 191P1 of the lower electrode and the second portion 191P2 of the lower electrode may be lower than the upper face 70US of the third electrode side wall support.

A part of the second portion 191P2 of the lower electrode may be disposed below the upper face 70US of the third electrode side wall support. The third electrode side wall support 70, which is the uppermost electrode side wall support SP_UM, may be in contact with a part of the side wall 191SW2 of the second portion of the lower electrode and a part of the side wall 191SW1 of the first portion of the lower electrode.

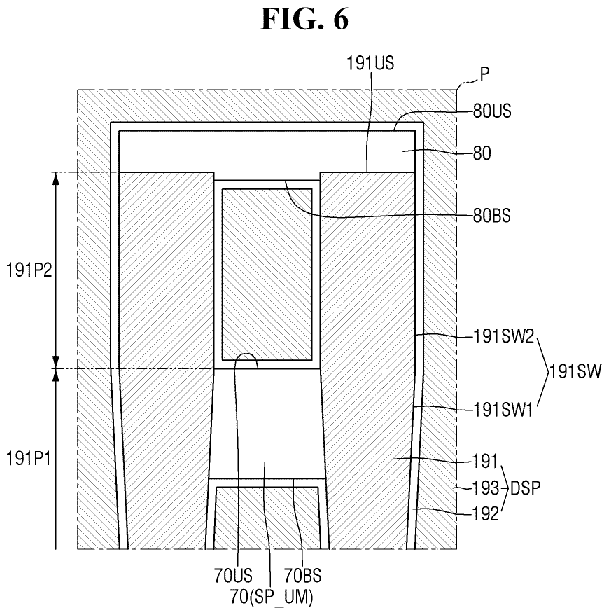

Referring to FIG. 6, in the semiconductor memory device according to some embodiments, the electrode capping support 80 may be in contact with the side wall 191SW of the lower electrode.

The electrode capping support 80 may be in contact with the side wall 191SW2 of the second portion of the lower electrode. The electrode capping support 80 may cover a part of the side wall 191SW2 of the second portion of the lower electrode.

The bottom face 80BS of the electrode capping support may include a first region that is in contact with the upper face 191US of the lower electrode, and a second region that is in contact with the capacitor dielectric film 192. With reference to the upper face of the conductive pattern (30 of FIG. 1), a first region of the bottom face 80BS of the electrode capping support may be higher than a second region of the bottom face 80BS of the electrode capping support.

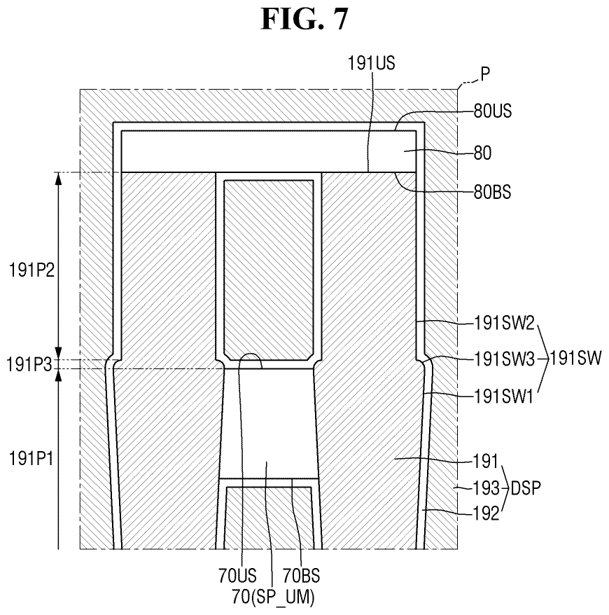

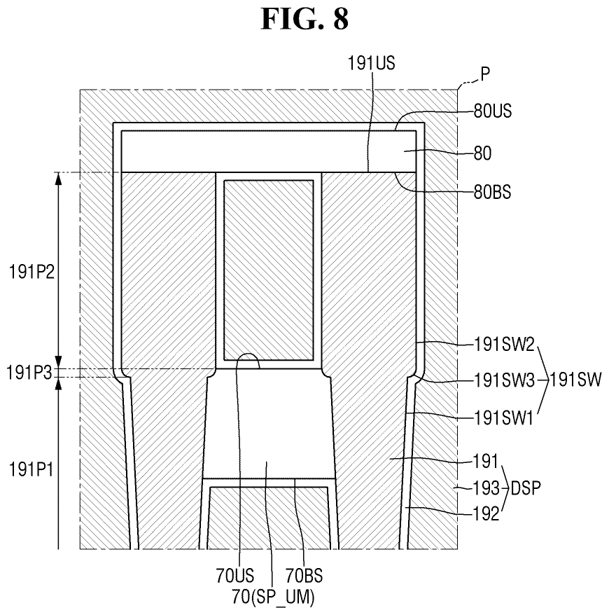

Referring to FIGS. 7 and 8, in the semiconductor memory device according to some embodiments, the lower electrode 191 may further include a third portion 191P3 disposed between the first portion 191P1 of the lower electrode and the second portion 191P2 of the lower electrode.

The side wall 191SW of the lower electrode includes a side wall 191SW3 of the third portion 191P3 of the lower electrode. The side wall 191SW3 of the third portion of the lower electrode may connect the side wall 191SW1 of the first portion of the lower electrode and the side wall 191SW2 of the second portion of the lower electrode. The side wall 191SW3 of the third portion of the lower electrode may have a rounded shape.

In FIGS. 3 and 7, the width in the first direction DR1 of the lower electrode 191 in the third portion 191P3 of the lower electrode may decrease, as it goes away from the first portion 191P1 of the lower electrode. For example, the third portion 191P3 may have a decreasing width in the fourth direction DR4 away from the first portion 191P of the lower electrode. The width of the third portion 191P3 may be measured in the first direction DR1. The third portion 191P3 of the lower electrode may protrude in the fourth direction DR4 beyond the upper face 70US of the third electrode side wall support.

In FIGS. 4 and 8, the width in the first direction DR1 of the lower electrode 191 in the third portion 191P3 of the lower electrode may increase, as it goes away from the first portion 191P1 of the lower electrode. For example, the third portion 191P3 of the lower electrode may have an increasing width in the fourth direction DR4 away from the lower first portion 191P1 of the lower electrode. The third portion 191P3 of the lower electrode may be disposed in the third electrode side wall support. The side wall 191SW3 of the third portion of the lower electrode may be in contact with the third electrode side wall support 70.

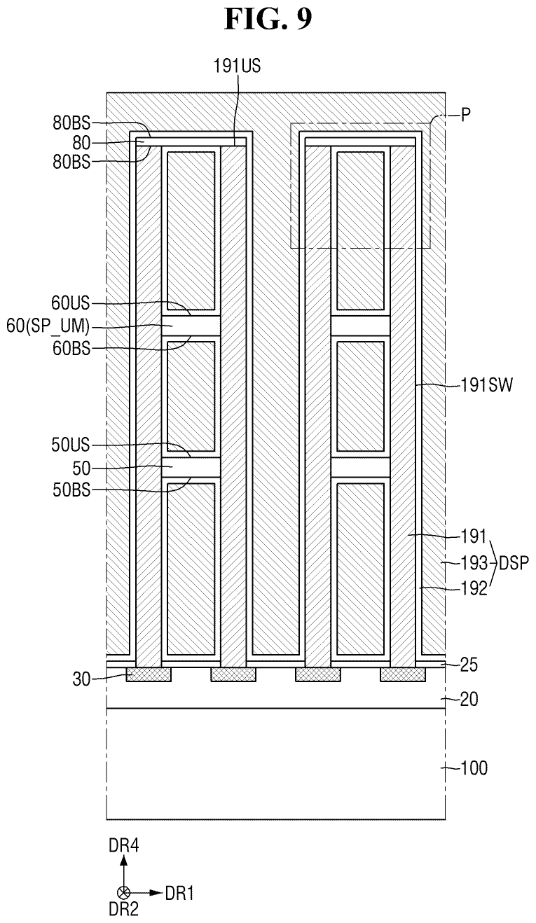

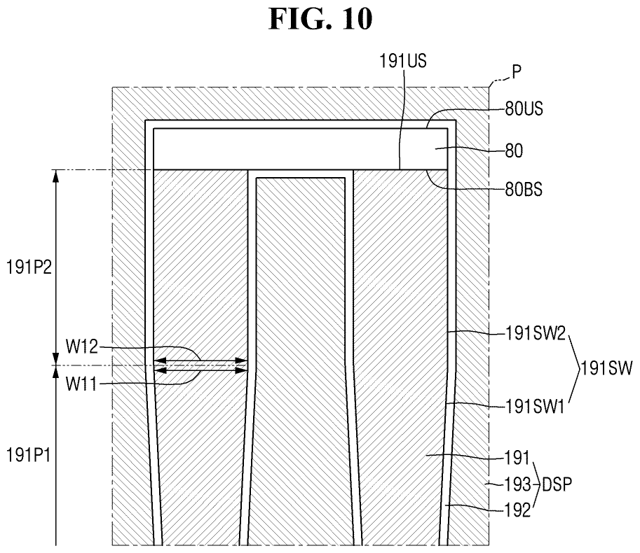

FIGS. 9 and 10 are diagrams for explaining a semiconductor memory device according to some embodiments. For convenience of explanation, the explanation will focus on the points that are different from those explained using FIGS. 1 and 2.

For reference, FIG. 10 is an enlarged view of a portion P of FIG. 9.

Referring to FIGS. 9 and 10, in the semiconductor memory device according to some embodiments, no electrode side wall support may be disposed near the boundary between the first portion 191P1 of the lower electrode and the second portion 191P2 of the lower electrode.

The third electrode side wall support (70 of FIG. 1) is not disposed between the electrode capping support 80 and the second electrode side wall support 60.

For example, the second electrode side wall support 60 may be the uppermost electrode side wall support SP_UM. A part of the first portion 191P1 of the lower electrode may protrude in the fourth direction DR4 beyond the upper face of the uppermost electrode side wall support SP_UM. A part of the first portion 191P1 of the lower electrode may protrude in the fourth direction DR4 beyond the upper face 60US of the second electrode side wall support.

The first electrode side wall support 50 and the second electrode side wall support 60 may be in contact with the side wall 191SW1 of the first portion of the lower electrode. The first electrode side wall support 50 and the second electrode side wall support 60 may not be in contact with the side wall 191SW2 of the second portion of the lower electrode.

Although FIG. 10 shows a shape in which the third electrode side wall support 70 is removed from FIG. 2, the embodiment is not limited thereto. In an embodiment, the enlarged view of the portion P of FIG. 9 may be the shapes of the lower electrode 191 and the electrode capping support 80 as shown in FIGS. 3, 4, and 6 to 8.

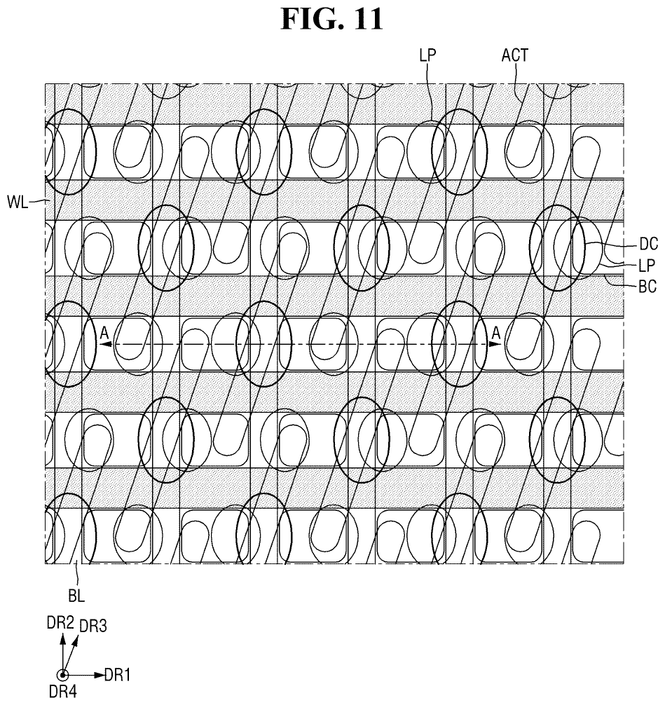

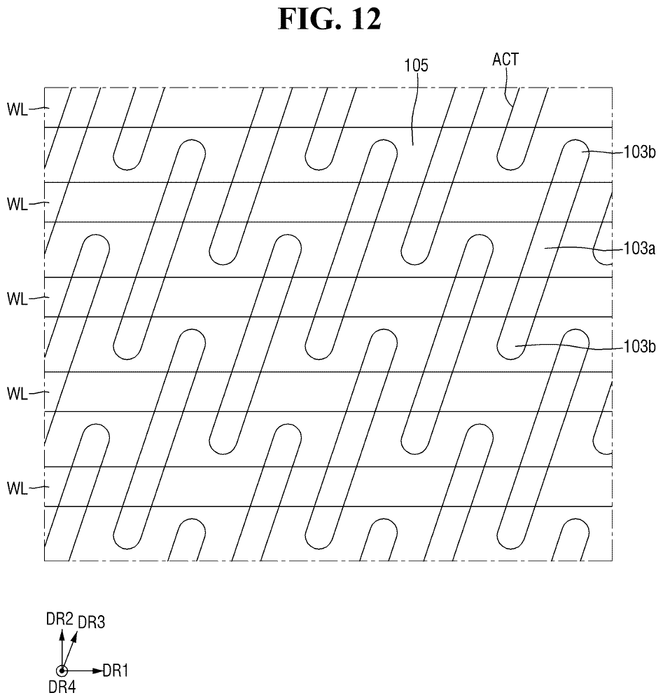

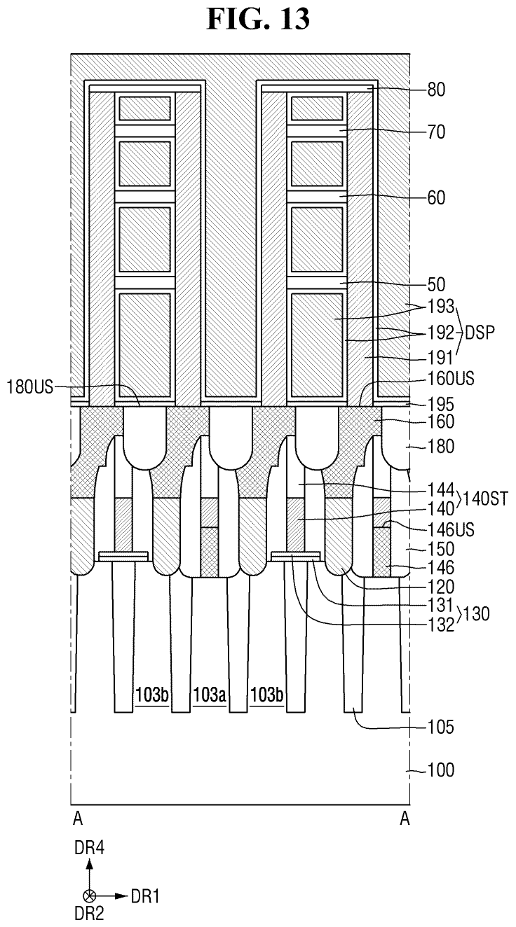

FIG. 11 is a layout diagram of a semiconductor memory device according to some embodiments. FIG. 12 is a layout showing a word line and a cell active region film of FIG. 11. FIG. 13 is a cross-sectional view taken along a line A-A of FIG. 11.

For reference, although FIG. 11 shows an example layout of a dynamic random access memory (DRAM) except a data storage pattern (DSP), the embodiment is not limited thereto.

Although the first direction DR1 of FIG. 11 may correspond to the first direction DR1 of FIG. 1, and the second direction DR2 of FIG. 11 may correspond to the second direction DR2 of FIG. 1, the embodiment is not limited thereto. Different from the above, the first direction DR1 of FIG. 11 may correspond to the second direction DR2 of FIG. 1, and the second direction DR2 of FIG. 11 may correspond to the first direction DR1 of FIG. 1.

Referring to FIGS. 11 and 12, a semiconductor memory device according to some embodiments may include a plurality of cell active regions ACT.

The cell active region ACT may be defined by a cell element separation film 105 formed in the substrate (100 of FIG. 13). As the design rules of the semiconductor memory devices decrease, the cell active region ACT may be disposed in the form of bar of diagonal line or opposite line, as shown. For example, the cell active region ACT may extend in a third direction DR3 between the first and second directions DR1 and DR2. The third direction DR3 may be parallel to the upper surface of the substrate 100.

A plurality of gate electrodes extending in the first direction DR1 across the cell active region ACT may be disposed. The plurality of gate electrodes may extend parallel to each other. The plurality of gate electrodes may be, for example, a plurality of word lines WL. The word lines WL may be disposed at regular intervals in the second direction DR2. A width of the word lines WL or an interval between the word lines WL may be determined according to design rules.

Each cell active region ACT may be divided into three portions by the two word lines WL extending in the first direction DR1. The cell active region ACT may include a storage connecting region 103b and a bit line connecting region 103a. The bit line connecting region 103a may be located at a central portion of the cell active region ACT, and the storage connecting region 103b may be located at an end portion of the cell active region ACT.

For example, the bit line connecting region 103a may be a region connected to the bit line BL, and the storage connecting region 103b may be a region connected to a data storage pattern (DSP of FIG. 13). In an embodiment, the bit line connecting region 103a may correspond to a common drain region, and the storage connecting region 103b may correspond to a source region. Each word line WL and the bit line connecting region 103a and storage connecting region 103b adjacent thereto may constitute a transistor.

A plurality of bit lines BL extending in the second direction DR2 orthogonal to the word line WL may be disposed on the word line WL. The plurality of bit lines BL may extend in parallel between each other. The bit lines BL may be disposed at regular intervals in the first direction DR1. The width of the bit lines BL or the interval between the bit lines BL may be determined according to design rules.

A fourth direction DR4 may be orthogonal to the first direction DR1, the second direction DR2, and the third direction DR3.

The semiconductor memory device according to some embodiments may include various contact arrangements formed on the cell active region ACT. Various contact arrangements may include, for example, a direct contact DC, a buried contact BC, and a landing pad LP.

Here, the direct contact DC may electrically connect the cell active region ACT to the bit line BL. The buried contact BC may electrically connect the cell active region ACT to a lower electrode (191 of FIG. 13) of the data storage pattern (DSP of FIG. 13).

In view of the placement structure, a contact area between the buried contact BC and the cell active region ACT may be small. Accordingly, a conductive landing pad LP may be introduced to increase the contact area with the cell active region ACT and increase the contact area with the lower electrode (191 of FIG. 13) of the data storage pattern.

In the semiconductor memory device according to some embodiments, the landing pad LP may be disposed between the buried contact BC and the data storage pattern. By enlarging the contact area through introduction of the landing pad LP, the contact resistance between the cell active region ACT and the lower electrode (191 of FIG. 13) of the data storage pattern may be reduced. In an embodiment, the introduction of the landing pad LP may increase a process margin for securing connection between the buried contact BC and the data storage pattern.

For example, the conductive pattern 30 of FIGS. 1 and 9 may correspond to the landing pad LP.

In the semiconductor devices according to some embodiments, the direct contact DC may be disposed in the central portion of the cell active region ACT. The buried contacts BC may be disposed at opposite distal end portions of the cell active region ACT. The direct contact DC may be connected to the bit line connecting region 103a. The buried contact BC may be connected to the storage connecting region 103b.

As the buried contacts BC are disposed at opposite distal end portions of the cell active region ACT, the landing pad LP may be disposed to partially overlap the buried contact BC to be adjacent to opposite distal ends of the cell active region ACT. For example, the buried contact BC may be formed to overlap the cell active region ACT and the element separation film (105 of FIG. 13) between adjacent word lines WL and between the adjacent bit lines BL.

The word line WL may be formed as a structure buried inside the substrate 100. The word line WL may be disposed across the cell active region ACT between the direct contacts DC or between the buried contacts BC.

In an embodiment, two word lines WL may be disposed to extend across one cell active region ACT. As the cell active region ACT is disposed obliquely, the word line WL may have an angle of less than 90 degrees with the cell active region ACT.

The direct contact DC and the buried contact BC may be disposed symmetrically.

Therefore, the direct contact DC and the buried contact BC may be disposed on a straight line along the first direction D1 and the second direction D2.

On the other hand, unlike the direct contact DC and the buried contact BC, the landing pad LP may be disposed in the form of a zigzag in the second direction D2 along which the bit line BL extends. In addition, the landing pad LP may be disposed to overlap the same side face portion of each bit line BL in the first direction D1 along which the word line WL extends.

For example, each of the landing pads LP of a first line overlaps a left side face of the corresponding bit line BL, and each of the landing pads LP of a second line may overlap a right side face of the corresponding bit line BL.

Referring to FIGS. 11 to 13, the semiconductor memory device according to some embodiments may include a plurality of bit line structures 140ST, a plurality of storage contacts 120, a plurality of bit line contacts 146, and a date storage pattern DSP.

The cell element separation film 105 may be disposed inside the substrate 100. The cell element separation film 105 may have a shallow trench isolation (STI) structure having excellent element separation characteristics. The cell element separation film 105 may define the cell active region ACT inside the memory cell region.

The cell active region ACT defined by the cell element separation film 105 may have a long island shape including a minor axis and a major axis, as shown in FIGS. 11 and 12. The cell active region ACT may have a form of an oblique line to have an angle of less than 90 degrees with respect to the word line WL formed inside the cell element separation film 105. The cell active region ACT may have a form of an oblique line to have an angle of less than 90 degrees with respect to the bit line BL formed on the cell element separation film 105.

The cell element separation film 105 may include or may be formed of, for example, but not limited to, at least one of a silicon oxide film, a silicon nitride film, and a silicon oxynitride film.

Although the cell element separation film 105 is shown as being formed as a single insulating film, this is merely for convenience of explanation, and the embodiment is not limited thereto. Depending on the spaced distance of the adjacent cell active regions ACT, the cell element separation film 105 may be formed of a single insulating film or may be formed of a plurality of insulating films.

Although FIG. 13 shows that the upper face of the cell element separation film 105 and the upper face of the substrate 100 are disposed on the same plane, this is only for convenience of explanation, and the embodiment is not limited thereto.

The bit line structure 140ST may include a cell conductive line 140, a cell line capping film 144, and a bit line spacer 150.

The cell conductive line 140 may be disposed on the substrate 100 on which the word line WL is formed and the cell element separation film 105. The cell conductive line 140 may intersect the cell element separation film 105 and the cell active region ACT defined by the cell element separation film 105. The cell conductive line 140 may be formed to intersect the word line WL. Here, the cell conductive line 140 may correspond to the bit line BL. For example, the cell conductive line 140 may be the bit line BL of FIG. 11.

The cell conductive line 140 may include or may be formed of, for example, at least one of an impurity-doped semiconductor material, a conductive silicide compound, a conductive metal nitride, a two-dimensional (2D) material, and a metal.

Although the cell conductive line 140 is shown as being a single film, this is only for convenience of explanation, and the embodiment is not limited thereto. In an embodiment, the cell conductive line 140 may include a plurality of conductive films in which the conductive materials are stacked.

The cell line capping film 144 may be disposed on the cell conductive line 140. The cell line capping film 144 may extend in the second direction DR2 along the upper face of the cell conductive line 140. The cell line capping film 144 may include or may be formed of, for example, at least one of a silicon nitride film, a silicon oxynitride film, a silicon carbonitride, and a silicon oxycarbonitride.

In the semiconductor memory device according to some embodiments, the cell line capping film 144 may include or may be a silicon nitride film. Although the cell line capping film 144 is shown as being a single film, the embodiment is not limited thereto.

The bit line spacer 150 may be disposed on the side walls of the cell conductive line 140 and the cell line capping film 144. The bit line spacer 150 extends long in the second direction DR2.

Although the bit line spacer 150 is shown as being a single film, this is only for convenience of explanation and the embodiment is not limited thereto. In an embodiment, the bit line spacer 150 may have a multi-film structure. The bit line spacer 150 may include or may be formed of, for example, but not limited to, one of a silicon oxide film, a silicon nitride film, a silicon oxynitride film (SiON), a silicon oxycarbonitride film (SiOCN), air, and a combination thereof.

The cell insulating film 130 may be disposed on the substrate 100 and the cell element separation film 105. For example, the cell insulating film 130 may be disposed on the upper faces of the substrate 100 and the cell element separation film 105 in which the bit line contact 146 and the storage contact 120 are not formed. The cell insulating film 130 may be formed between the substrate 100 and the cell conductive line 140 and between the cell element separation film 105 and the cell conductive line 140.

The cell insulating film 130 may be a single film. In an embodiment, the cell insulating film 130 may be a multi-film including a first cell insulating film 131 and a second cell insulating film 132. For example, the first cell insulating film 131 may include or may be formed of a silicon oxide film, and the second cell insulating film 132 may include or may be formed of a silicon nitride film, but the embodiment is not limited thereto. In an embodiment, the cell insulating film 130 may be, but not limited to, a triple film including a silicon oxide film, a silicon nitride film, and a silicon oxide film.

The bit line contact 146 may be disposed between the cell conductive line 140 and the substrate 100. The cell conductive line 140 may be disposed on the bit line contact 146.

The bit line contact 146 may be disposed between a bit line connecting portion 103a of the cell active region ACT and the cell conductive line 140. The bit line contact 146 may electrically connect the cell conductive line 140 and the substrate 100. The bit line contact 146 may be connected to the bit line connecting portion 103a.

The bit line contact 146 may include an upper face 146US connected to the cell conductive line 140. The width of the bit line contact 146 in the first direction DR1 may be constant as it goes away from the upper face 146US of the bit line contact. For example, the bit line contact 146 may have a constant width in the fourth direction DR4. This is only for convenience of explanation, and the embodiment is not limited thereto.

The bit line contact 146 may correspond to a direct contact DC. The bit line contact 146 may include or may be formed of, for example, at least one of an impurity-doped semiconductor material, a conductive metal silicide, a conductive metal nitride, a conductive metal oxide, a metal, and a metal alloy.

In the portion of the cell conductive line 140 in which the bit line contact 146 is formed, a bit line spacer 150 may be disposed on the substrate 100 and the cell element separation film 105. The bit line spacer 150 may be disposed on the side walls of the cell conductive line 140, the cell line capping film 144, and the bit line contact 146.

In the remaining portion of the cell conductive line 140 in which the bit line contact 146 is not formed, the bit line spacer 150 may be disposed on the cell insulating film 130. The bit line spacer 150 may be disposed on the side walls of the cell conductive line 140 and the cell line capping film 144.

The storage contact 120 may be disposed between the cell conductive lines 140 adjacent in the first direction DR1. The storage contact 120 may be disposed on opposite sides of the cell conductive line 140. For example, the storage contact 120 may be disposed between the bit line structures 140ST. The storage contact 120 may be disposed between the word lines WL adjacent in the second direction DR2.

The storage contact 120 may overlap the substrate 100 and the cell element separation film 105 between adjacent cell conductive lines 140. The storage contact 120 may be connected to the cell active region ACT. For example, the storage contact 120 may be connected to the storage connecting portion 103b. Here, the storage contact 120 may correspond to the buried contact BC of FIG. 1.

The storage contact 120 may include or may be formed of, for example, at least one of a semiconductor material doped with impurities, a conductive silicide compound, a conductive metal nitride, a conductive metal carbide, a conductive metal carbonitride, a conductive metal oxide, and a metal.

A storage pad 160 may be disposed on the storage contact 120. The storage pad 160 may be electrically connected to the storage contact 120. The storage pad 160 may be connected to the storage connecting portion 103b of the cell active region ACT. Here, the storage pad 160 may correspond to the landing pad LP of FIG. 11.

The storage pad 160 may overlap a part of the upper face of the bit line structure 140ST. The storage pad 160 may include or may be formed of, for example, at least one of a conductive silicide compound, a conductive metal nitride, a conductive metal carbide, a conductive metal oxide, and a metal.

The pad separation insulating film 180 may be disposed on the storage pad 160 and the bit line structure 140ST. For example, the pad separation insulating film 180 may be disposed on the cell line capping film 144.

The pad separation insulating film 180 may define a storage pad 160 that forms a plurality of isolation regions. The pad separation insulating film 180 may not cover the upper face 160US of the storage pad. For example, the height of the upper face 160US of the storage pad may be equal to the height of the upper face 180US of the pad separation insulating film with reference to the upper face of the substrate 100. In an embodiment, the upper face 160US of the storage pad may be coplanar with the upper face 180US of the pad separation insulating film.

The pad separation insulating film 180 may include or may be formed of an insulating material, and may electrically separate the plurality of storage pads 160 from each other. For example, the pad separation insulating film 180 may include or may be formed of, but not limited to, at least one of a silicon oxide film, a silicon nitride film, a silicon oxynitride film, a silicon oxycarbonitride film, and a silicon carbonitride film.

A second etching stop film 195 may be disposed on the upper face 160US of the storage pad and the upper face 180US of the pad separation insulating film. For example, the second etching stop film 195 may correspond to the first etching stop film 25 of FIGS. 1 and 9.

The second etching stop film 195 may include or may be formed of, for example, at least one of silicon nitride (SiN), silicon carbonitride (SiCN), silicon oxycarbonitride (SiOCN), silicon oxycarbide (SiOC), and silicon boronitride (SiBN).

The data storage patterns DSP may be disposed on the storage pad 160. The data storage pattern DSP is electrically connected to the storage pad 160. A part of the data storage pattern DSP may be disposed in the second etching stop film 195.

The data storage pattern DSP may include, for example, a capacitor. The data storage pattern DSP includes a lower electrode 191, a capacitor dielectric film 192, and an upper electrode 193.

The first to third electrode side wall supports 50, 60, and 70 may support the lower electrode 191. The first to third electrode side wall supports 50, 60, and 70 may be in contact with the lower electrode 191.

The electrode capping support 80 may be disposed on the lower electrode 191. The electrode capping support 80 may be in contact with the upper face of the lower electrode 191.

Descriptions of the lower electrode 191, the capacitor dielectric film 192, and the upper electrode 193 may be substantially the same as those described with reference to FIGS. 1 to 10, and therefore will not be provided below.

Descriptions of the first to third electrode side wall supports 50, 60, and 70 and the electrode capping support 80 may be substantially the same as those described using FIGS. 1 to 10, and therefore will not be provided below.

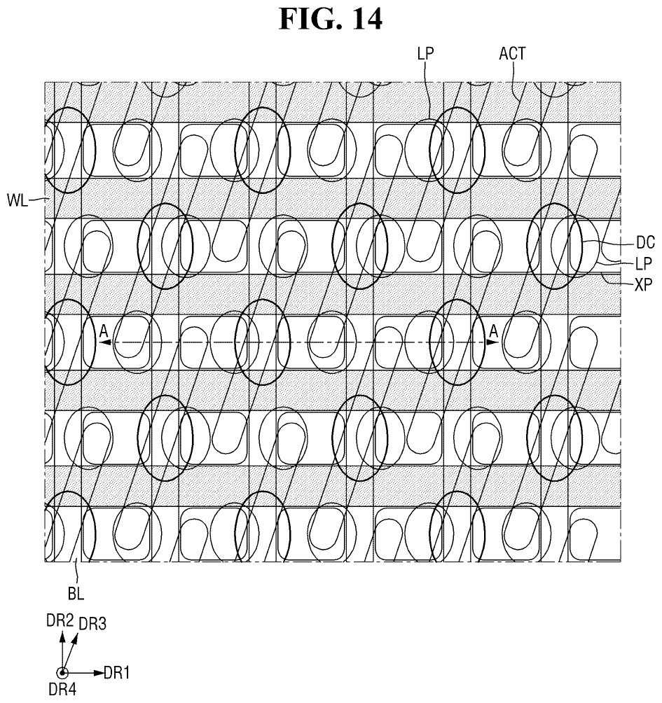

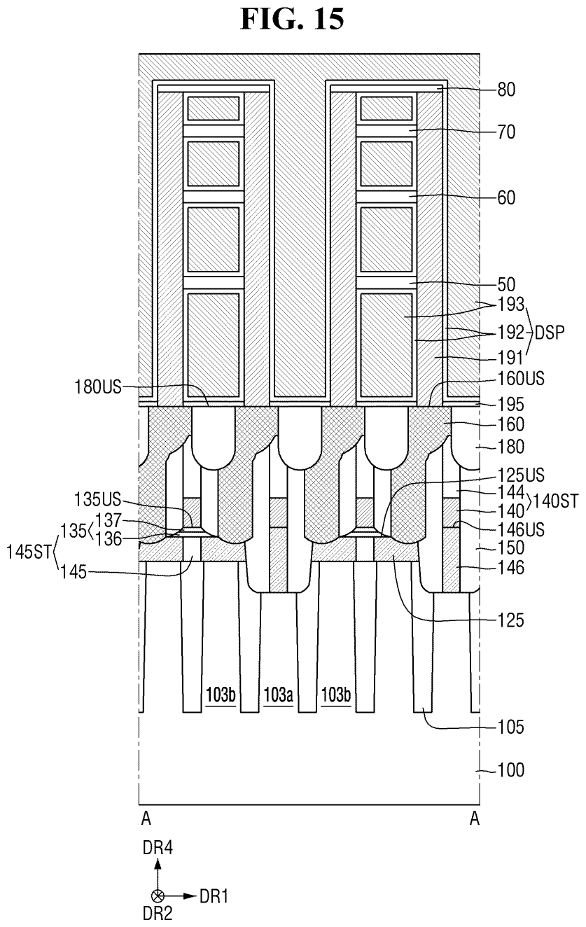

FIGS. 14 and 15 are diagrams for explaining a semiconductor memory device according to some embodiments. For convenience of explanation, points different from those described using FIGS. 11 to 13 will be mainly explained.

FIG. 14 is a layout of a semiconductor memory device according to some embodiments. FIG. 15 is a cross-sectional view taken along a line A-A of FIG. 14.

Referring to FIGS. 12, 14, and 15, the semiconductor memory device according to some embodiments may include a node pad XP disposed on the substrate 100.

The node pad XP may be disposed in place of the buried contact BC of FIG. 11. The node pad XP may be a connecting pad that connects the cell active region ACT to the lower electrode 191 of the data storage pattern DSP. The node pad XP may be connected to the storage connecting region 103b.

Due to the arrangement structure, the contact area between the node pad XP and the cell active region ACT may be small. Therefore, in order to increase the contact area with the cell active region ACT and the contact area with the lower electrode 191 of the data storage pattern DSP, a conductive landing pad LP may be introduced.

As the node pads XP are disposed at opposite distal end portions of the cell active region ACT, the landing pads LP may be disposed to at least partially overlap the node pads XP to be adjacent to opposite distal ends of the cell active region ACT. For example, the node pad XP may be formed to overlap the cell active region ACT and the cell element separation film 105 between the adjacent word lines WL and between the adjacent bit lines BL.

The word line WL may be disposed to extend across the cell active region ACT between the direct contact DC and the node pad XP. The direct contact DC and the node pad XP may be disposed symmetrically. Accordingly, the direct contact DC and the node pad XP may be disposed on a straight line along the first direction DR1 and the second direction DR2.

The node connecting pad 125 may be disposed on the substrate 100 and the cell element separation film 105. The node connecting pad 125 may be disposed on the upper face of the cell element separation film 105.

A bottom face of the node connecting pad 125 may be disposed on the upper face of the cell element separation film 105. The bottom face of the node connecting pad 125 may be in contact with the upper face of the cell element separation film 105. For example, the entire node connecting pad 125 may be disposed on the upper face of the substrate 100. Here, the node connecting pad 125 may correspond to the node pad XP.

The upper face 125US of the node connecting pad may be lower than the upper face 146US of the bit line contact with reference to the upper face of the cell element separation film 105. The upper face 125US of the node connecting pad may be lower than the bottom face of the cell conductive line 140 with reference to the upper face of the cell element separation film 105.

The contact separation structure 145ST may separate the node connecting pads 125 adjacent in the first direction DR1 from each other. Although not shown, the contact separation structure 145ST may separate the node connecting pads 125 adjacent in the second direction DR2 from each other. The contact separation structure 145ST covers the upper face 125US of the node connecting pad.

The contact separation structure 145ST may include a contact separation pattern 145 and an upper cell insulating film 135. The upper cell insulating film 135 may be disposed on the contact separation pattern 145.

The node connecting pad 125 may include a first node connecting pad and a second node connecting pad that are spaced apart from each other in the first direction DR1, and the contact separation pattern 145 may separate the first node connecting pad and the second node connecting pad in the first direction DR1 from each other. In an embodiment, the contact separation pattern 145 may also separate the node connecting pads 125 adjacent to each other in the second direction DR2 from each other.

The entire upper face 125US of the node connecting pad may not be in contact with the entire storage pad 160. For example, a width of an interface between the node connecting pad 121 and the storage pad 160 in the first direction DR1 may be smaller than the width of the upper face 125US of the node connecting pad in the first direction DR1.

The bit line spacer 150 may be disposed on the upper face 125US of the node connecting pad.

The upper cell insulating film 135 may cover the upper face 125US of the node connecting pad. The node connecting pad 125 may include a first node connecting pad and a second node connecting pad that are spaced apart from each other in the first direction DR1, and the upper cell insulating film 135 may cover the upper face of the first node connecting pad and the upper face of the second node connecting pad.

The upper face 135US of the upper cell insulating film may be disposed on the same plane as (i.e., may be coplanar with) the upper face 146US of the bit line contact. For example, the height of the upper face 135US of the upper cell insulating film may be the same as the height of the upper face 146US of the bit line contact with reference to the upper face of the cell element separation film 105.

The cell conductive line 140 may be disposed on the upper face of the contact separation structure 145ST. The cell conductive line 140 may be disposed on the upper face 135US of the upper cell insulating film. The upper face of the contact separation structure 145ST may be the upper face 135US of the upper cell insulating film. The upper face of the contact separation structure 145ST may be disposed on the same plane as (i.e., may be coplanar with) the bottom face of the cell conductive line 140.

The contact separation pattern 145 may include or may be formed of, for example, at least one of silicon nitride (SiN), silicon oxynitride (SiON), silicon oxide (SiO₂), silicon carbonitride (SiCN), silicon oxycarbonitride (SiOCN), and a combination thereof. The upper cell insulating film 135 may be a single film. In an embodiment, the upper cell insulating film 135 may be a multi-film that includes a first upper cell insulating film 136 and a second upper cell insulating film 137. For example, the first upper cell insulating film 136 may include or may be formed of a silicon oxide film, and the second upper cell insulating film 137 may include or may be formed of a silicon nitride film, but the present disclosure is not limited thereto. Although the width of the upper cell insulating film 135 in the first direction DR1 is shown to decrease as it goes away from the substrate 100, the embodiment is not limited thereto.

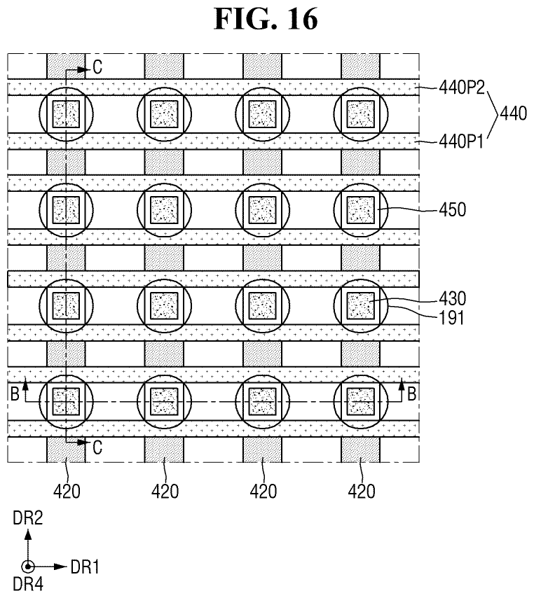

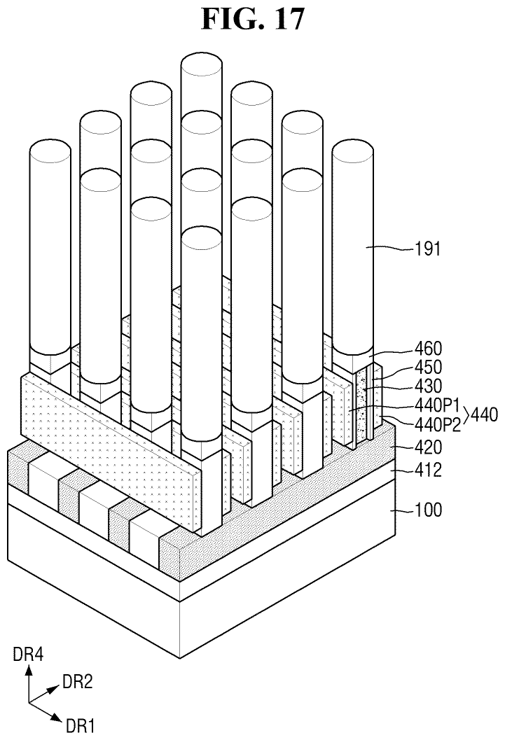

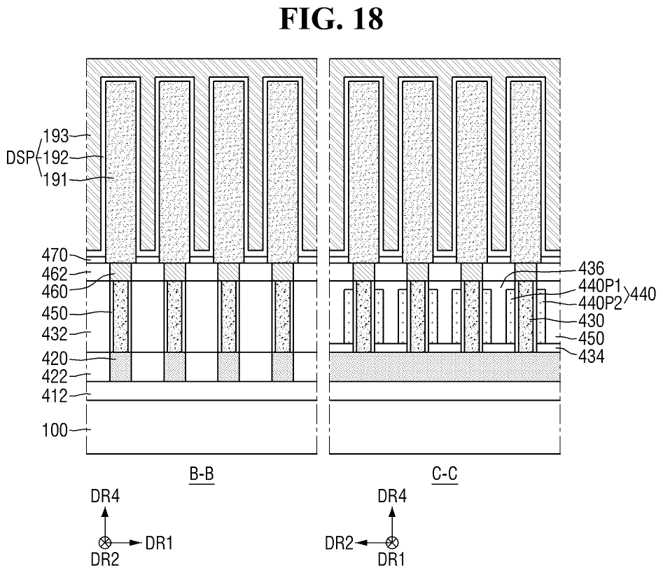

FIG. 16 is a layout diagram for explaining a semiconductor memory device according to some embodiments. FIG. 17 is a perspective view for explaining the semiconductor memory device according to some embodiments. FIG. 18 is a cross-sectional view taken along lines B-B and C-C of FIG. 16.

For convenience of explanation, the first to third electrode side wall supports 50, 60 and 70 and the electrode capping support 80 are omitted from FIG. 18. [Stop Here]

Referring to FIGS. 16 to 18, the semiconductor memory device according to some embodiments may include a substrate 100, a plurality of first conductive lines 420, a channel layer 430, a gate electrode 440, a gate insulating film 450, and a data storage pattern DSP.

The semiconductor memory device according to some embodiments may be a memory device including a vertical channel transistor (VCT). The vertical channel transistor may refer to a transistor in which a channel length of the channel layer 430 extends from the substrate 100 in a vertical direction.

A lower insulating layer 412 may be disposed on the substrate 100. A plurality of first conductive lines 420 may be spaced apart from each other in the first direction DR1 on the lower insulating layer 412 and extend in the second direction DR2. A plurality of first insulating patterns 422 may be disposed on the lower insulating layer 412 to fill the space between the plurality of first conductive lines 420. The plurality of first insulating patterns 422 may extend in the second direction DR2. The upper faces of the plurality of first insulating patterns 422 may be disposed at the same level as (i.e., may be coplanar with) the upper faces of the plurality of first conductive lines 420. The plurality of first conductive lines 420 may function as bit lines.

The plurality of first conductive lines 420 may include or may be formed of doped semiconductor material, metal, conductive metal nitride, conductive metal silicide, conductive metal oxide or a combination thereof. For example, the plurality of first conductive lines 420 may be made up of, but not limited to, doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOₓ, RuOₓ or a combination thereof. The plurality of first conductive lines 420 may include a single layer or multiple layers of the above-mentioned materials. In example embodiments, the plurality of first conductive lines 420 may include or may be formed of graphene, carbon nanotube or a combination thereof.

The channel layers 430 may be arranged in the form of a matrix and may be disposed apart from each other in the first direction DR1 and the second direction DR2 on the plurality of first conductive lines 420. Each of the channel layers 430 may have a first width along the first direction DR1 and a first height along the second direction DR2, and the first height may be greater than the first width. Here, the fourth direction DR4 may be a direction that intersects the first direction DR1 and the second direction DR2, and for example, perpendicular to the upper face of the substrate 100. For example, the first height may be, but not limited to, about 2 to 10 times the first width. A bottom portion of the channel layer 430 may function as a third source/drain region (not shown), an upper portion of the channel layer 430 may function as a fourth source/drain region (not shown), and a part of the channel layer 430 between the third and fourth source/drain regions may function as a channel region (not shown).

In an embodiment, the channel layer 430 may include an oxide semiconductor, and the oxide semiconductor may include, for example, InₓGa_{y}Zn_{z}O, InₓGa_{y}Si_{z}O, InₓSn_{y}Zn₂O, InₓZn_{y}O, ZnₓO, ZnₓSn_{y}O, ZnₓO_{y}N, ZrₓZn_{y}Sn_{z}O, SnₓO, HfₓIn_{y}Zn₂O, GaₓZn_{y}Sn_{z}O, AlₓZn_{y}Sn_{z}O, YbₓGa_{y}Zn_{z}O, InₓGa_{y}O or a combination thereof. The channel layer 430 may include a single layer or multiple layers of the oxide semiconductor. In some embodiments, the channel layer 430 may have a bandgap energy that is greater than the bandgap energy of silicon. For example, the channel layer 430 may have a bandgap energy of about 1.5 eV to 5.6 eV. For example, the channel layer 430 with the bandgap energy of about 2.0 eV to 4.0 eV may have desired channel performance. For example, the channel layer 430 may be, but not limited to, polycrystalline or amorphous. In an embodiment, the channel layer 430 may include graphene, carbon nanotube or a combination thereof. In an embodiment, the channel layer 430 may include a silicon-based semiconductor material. The channel layer 430 may include a single crystal semiconductor material, and may include, but not limited to, single crystal silicon or single crystal silicon-germanium.

The gate electrode 440 may extend in the first direction DR1 on opposite side walls of the channel layer 430. The gate electrode 440 may include a first sub-gate electrode 440P1 that faces a first side wall of the channel layer 430, and a second sub-gate electrode 440P2 that faces a second side wall opposite to the first side wall of the channel layer 430. For example, the first sub-gate electrode 440P1 may be adjacent to the first side wall of the channel layer 430, and the second sub-gate electrode 440P2 may be adjacent to the second side wall opposite to the first side wall of the channel layer 430. As the single channel layer 430 is disposed between the first sub-gate electrode 440P1 and the second sub-gate electrode 440P2, the semiconductor device may have a dual gate transistor structure. However, the technical idea of the present disclosure is not limited thereto. In an embodiment, the second sub-gate electrode 440P2 may be omitted, and only the first sub-gate electrode 440P1 that faces the first side wall of the channel layer 430 may be formed to implement a single gate transistor structure.

The gate electrode 440 may include or may be formed of at least one of a metal, a conductive metal nitride, a conductive metal carbonitride, a conductive metal carbide, a metal silicide, a doped semiconductor material, a conductive metal oxynitride, and a conductive metal oxide. The gate electrode 440 may include or may be formed of, for example, but not limited to, at least one of TiN, TaC, TaN, TiSiN, TaSIN, TaTiN, TiAIN, TaAIN, WN, Ru, TiAl, TiAIC-N, TiAIC, TiC, TaCN, W, Al, Cu, Co, Ti, Ta, Ni, Pt, Ni—Pt, Nb, NbN, NbC, Mo, MON, MOC, WC, Rh, Pd, Ir, Ag, Au, Zn, V, RuTiN, TiSi, TaSi, NiSi, CoSi, IrOₓ, RuOₓ, and a combination thereof.

The gate insulating film 450 surrounds the side walls of the channel layer 430, and may be interposed between the channel layer 430 and the gate electrode 440. For example, as shown in FIG. 16, the entire side walls of the channel layer 430 may be surrounded by the gate insulating film 450, and a part of the side walls of the gate electrode 440 may contact the gate insulating film 450. In some embodiments, the gate insulating film 450 may extend in an extension direction (i.e., the first direction DR1) of the gate electrode 440, and only two side walls that face the gate electrode 440 among the side walls of the channel layer 430 may contact the gate insulating film 450.

The gate insulating film 450 may include or may be formed of, for example, at least one of silicon oxide, silicon nitride, silicon oxynitride and a high dielectric constant material having a higher dielectric constant than that of silicon oxide. The high dielectric constant material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

A plurality of second insulating patterns 432 may extend on the plurality of first insulating patterns 422 along the second direction DR2. The channel layer 430 may be disposed between two adjacent second insulating patterns 432 among the plurality of second insulating patterns 432. A first buried layer 434 and a second buried layer 436 may be disposed between two adjacent second insulating patterns 432 and in a space between two adjacent channel layers 430. The first buried layer 434 may be located at the bottom portion of the space between two adjacent channel layers 430. The second buried layer 436 may be formed to fill the remainder of the space between two adjacent channel layers 430 on the first buried layer 434. The upper face of the second buried layer 436 may be disposed at the same level as (i.e., may be coplanar with) the upper face of the channel layer 430, and the second buried layer 436 may cover the upper face of the second gate electrode 440. The plurality of second insulating patterns 432 may be formed of a material layer that is continuous with the plurality of first insulating patterns 422, or the second buried layer 436 may be formed of a material layer that is continuous with the first buried layer 434.

A capacitor contact 460 may be disposed on the channel layer 430. The capacitor contacts 460 may be disposed to overlap the channel layer 430 in the vertical direction, and may be arranged in the form of a matrix and may be spaced apart from each other in the first direction DR1 and the third direction DR3. The capacitor contacts 460 may be made up of, but not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ or a combination thereof. The upper insulating film 462 may surround the side walls of the capacitor contacts 460 on the plurality of second insulating patterns 432 and the second buried layer 436.

A third etching stop film 470 may be disposed on the upper insulating layer 462. A data storage pattern DSP may be disposed on the third etching stop film 470. The data storage pattern DSP may include a lower electrode 191, a capacitor dielectric film 192, and an upper electrode 193. The lower electrode 191 may pass through the third etching stop film 470, and may be electrically connected to the upper face of the capacitor contact 460.

In some embodiments, the lower electrodes 191 are disposed to vertically overlap the capacitor contacts 460, and may be disposed in the form of a matrix in which the capacitor contacts 460 are spaced apart in the first direction DR1 and the second direction DR2. A landing pad (not shown) may be further disposed between the capacitor contact 460 and the lower electrode 191, and the lower electrode 191 may be disposed in a hexagonal shape.

Descriptions of the lower electrode 191, the capacitor dielectric film 192, and the upper electrode 193 may be substantially the same as those described using FIGS. 1 to 10, and therefore will not be provided below.

Although the first to third electrode side wall supports 50, 60 and 70 and the electrode capping support 80 are not shown in FIG. 18, description of the first to third electrode side wall supports 50, 60 and 70 and the electrode capping support 80 may be substantially the same as that described with reference to FIGS. 1 to 10.

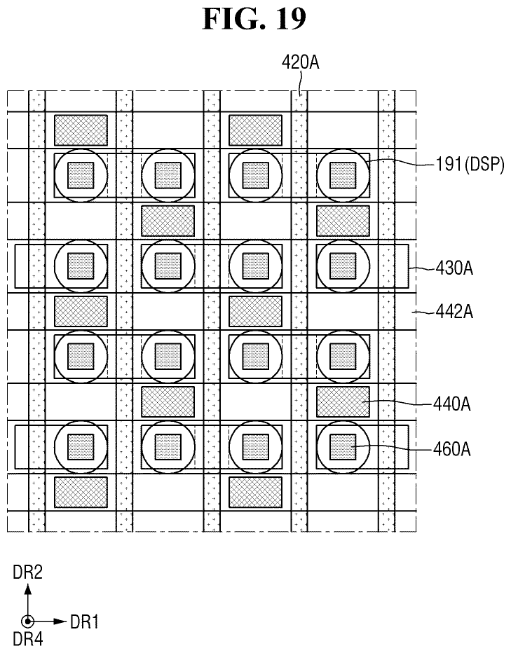

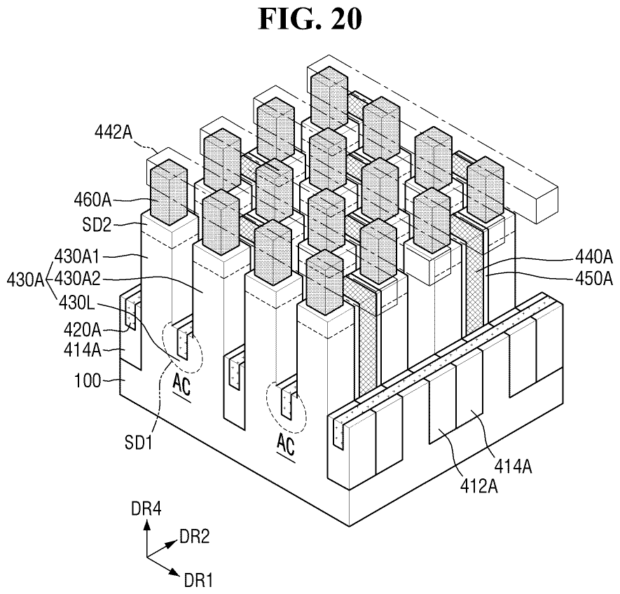

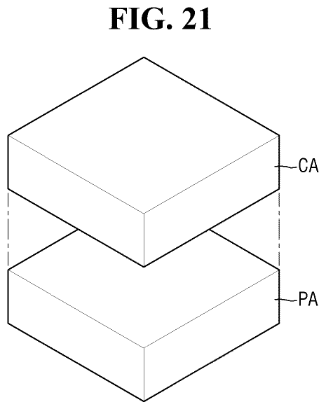

FIG. 19 is a layout diagram for explaining a semiconductor memory device according to some embodiments. FIG. 20 is a perspective view for explaining a semiconductor memory device according to some embodiments. FIG. 21 is a diagram for explaining a semiconductor memory device according to some embodiments.

Referring to FIGS. 19 and 20, the semiconductor memory device according to some embodiments may include a substrate 100, a plurality of first conductive lines 420A, a channel structure 430A, a contact gate electrode 440A, a plurality of second conductive lines 442A, and a data storage pattern DSP. The semiconductor memory device according to some embodiments may be a memory device including a vertical channel transistor (VCT).

A plurality of active regions AC may be defined in the substrate 100 by a first element separation pattern 412A and a second element separation pattern 414A. The channel structure 430A may be disposed in each active region AC. The channel structure 430A may include a first active pillar 430A1 and a second active pillar 430A2 that each extend in the vertical direction, and a connecting portion 430L that is connected to the bottom portion of the first active pillar 430A1 and the bottom portion of the second active pillar 430A2. A first source/drain region SD1 may be disposed in the connecting portion 430L. A second source/drain region SD2 may be disposed above the first and second active pillars 430A1 and 430A2. The first active pillar 430A1 and the second active pillar 430A2 may each constitute an independent unit memory cell.

The plurality of first conductive lines 420A may extend in a direction intersecting each of the plurality of active regions AC, and may extend, for example, in the second direction DR2. One first conductive line 420A among the plurality of first conductive lines 420A may be disposed on the connecting portion 430L between the first active pillar 430A1 and the second active pillar 430A2. One first conductive line 420A may be disposed on the first source/drain region SD1. Another first conductive line 420A adjacent to one first conductive line 420A may be disposed between two channel structures 430A. One of the plurality of first conductive lines 420A may function as a common bit line included in the two unit memory cells constituted by the first active pillar 430A1 and the second active pillar 430A2 disposed on opposite sides of one first conductive line 420A.

One contact gate electrode 440A may be disposed between two channel structures 430A adjacent to each other in the second direction DR2. For example, the contact gate electrode 440A may be disposed between the first active pillar 430A1 included in one channel structure 430A and the second active pillar 430A2 of the channel structure 430A adjacent thereto. One contact gate electrode 440A may be shared by the first active pillar 430A1 and the second active pillar 430A2 disposed on opposite side walls thereof. A gate insulating film 450A may be disposed between the contact gate electrode 440A and the first active pillar 430A1, and between the contact gate electrode 440A and the second active pillar 430A2. The plurality of second conductive lines 442A may extend in the first direction D1 on the upper face of the contact gate electrode 440A. The plurality of second conductive lines 442A may function as word lines of a semiconductor memory device.

A capacitor contact 460A may be disposed on the channel structure 430A. The capacitor contact 460A may be disposed on the second source/drain region SD2, and the data storage pattern DSP may be disposed on the capacitor contact 460A.

Referring to FIG. 21, the semiconductor memory device according to some embodiments may have a cell on periphery (COP) structure in which a cell array region CA is disposed on a peri-structure region PA.

The cell array region CA may include the vertical channel transistors VCT of FIGS. 16 to 20. A sensing transistor, a transfer transistor, a driving transistor, and the like connected to the vertical channel transistor of FIGS. 16 to 20 may be disposed in the peri-structure region PA.

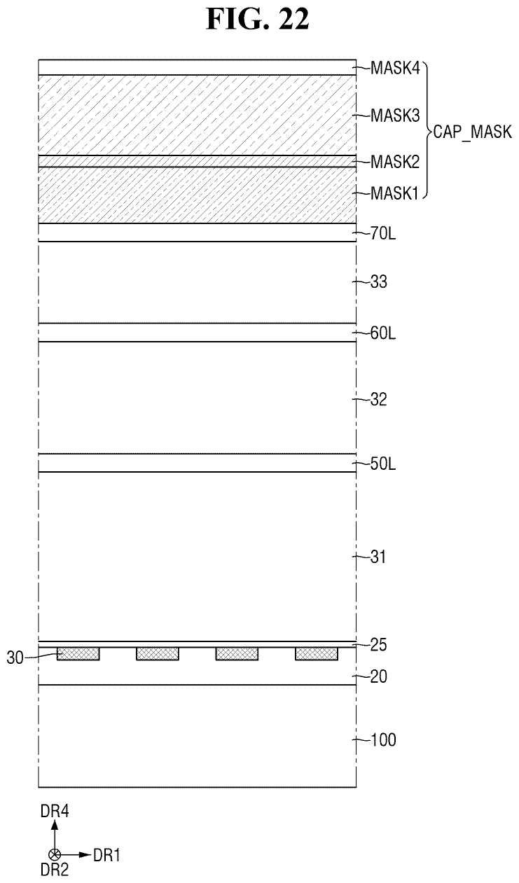

FIGS. 22 to 33 are intermediate step diagrams for explaining a method of fabricating a semiconductor memory device according to some embodiments. For convenience of explanation, repeated parts of those described using FIGS. 1 to 10 will be briefly described or omitted.

Referring to FIG. 20, the interlayer insulating film 20 may be formed on the substrate 100.

The conductive pattern 30 may be formed in the interlayer insulating film 20. The first etching stop film 25 may be formed on the conductive pattern 30 and the interlayer insulating film.

The first mold insulating film 31, the first electrode support film 50L, the second mold insulating film 32, the second electrode support film 60L, the third mold insulating film 33, and the third electrode support film 70L may be formed sequentially on the first etching stop film 25.

Each of the first mold insulating film 31, the second mold insulating film 32, and the third mold insulating film 33 may include or may be formed of, but not limited to, at least one of silicon oxide, silicon nitride, silicon oxynitride, and a low dielectric (low-k) material having a dielectric constant smaller than that of silicon oxide.

Each of the first electrode support film 50L, the second electrode support film 60L, and the third electrode support film 70L may include or may be formed of, but not limited to, at least one of silicon nitride, silicon carbonitride, silicon boron nitride, silicon carbonate, silicon oxynitride, and silicon oxycarbonitride.

In an embodiment, the third electrode support film 70L may not be formed.

A capacitor mask film CAP_MASK may be formed on the third electrode support film 70L. The capacitor mask film CAP_MASK may include a plurality of films that are sequentially formed on the third electrode support film 70L.

For example, the capacitor mask film CAP_MASK may include a first mask film MASK1, a second mask film MASK2, a third mask film MASK3, and a fourth mask film MASK4. The first mask film MASK1, the second mask film MASK2, the third mask film MASK3, and the fourth mask film MASK4 may be sequentially formed on the third electrode support film 70L.

Each of the first mask film MASK1 and the third mask film MASK3 may include or may be formed of a semiconductor material. For example, each of the first mask film MASK1 and the third mask film MASK3 may include or may be formed of, but not limited to, at least one of polycrystalline silicon, amorphous silicon, polycrystalline silicon-germanium, amorphous silicon-germanium, polycrystalline germanium, and amorphous germanium.

The second mask film MASK2 may include or may be formed of a conductive material. For example, the second mask film MASK2 may include or may be formed of the same material as that of the lower electrode 191.

The fourth mask film MASK4 may include or may be formed of, for example, but not limited to, silicon oxide.

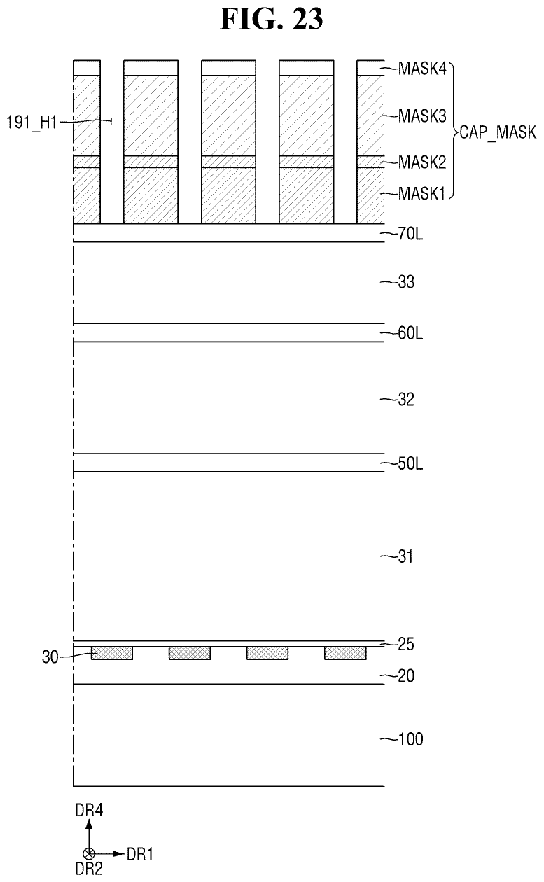

Referring to FIGS. 22 and 23, a lower electrode mask hole 191_H1 may be formed in the capacitor mask film CAP_MASK.

The lower electrode mask hole 191_H1 may pass through the capacitor mask film CAP_MASK. The lower electrode mask hole 191_H1 may expose the third electrode support film 70L. When the third electrode support film 70L is not formed, the lower electrode mask hole 191_H1 may expose the third mold insulating film 33.

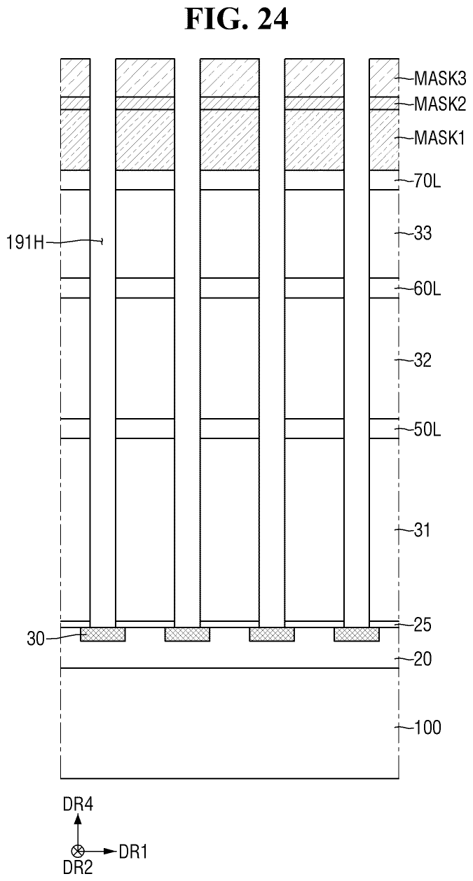

Referring to FIGS. 23 and 24, a lower electrode hole 191H may be formed inside the first to third electrode support films 50L, 60L, and 70L, the first to third mold insulating films 31, 32, and 33, by using the lower electrode mask hole 191_H1.

The lower electrode hole 191H may pass through the first etching stop film 25. The lower electrode hole 191H may expose the conductive pattern 30.

The lower electrode hole 191H may include a part of the lower electrode mask hole 191_H1. While the lower electrode hole 191H is being formed, a part of the third mask film MASK3 and the fourth mask film MASK4 in the capacitor mask film CAP_MASK may be removed. In an embodiment, the entire third mask film MASK3 may be removed while the lower electrode hole 191H is being formed.

The slope of the side wall of the lower electrode hole 191H may vary depending on which property of material the lower electrode hole 191H is formed. For example, the slope of the side wall of the lower electrode hole 191H in the first mask film MASK1 including a semiconductor material may be different from the slope of the side wall of the lower electrode hole 191H in the third electrode support film 70L and the third mold insulating film 33 including an insulating material. The slope of the side wall of the lower electrode hole 191H may vary in the vicinity of the boundary between the third electrode support film 70L and the first mask film MASK1.

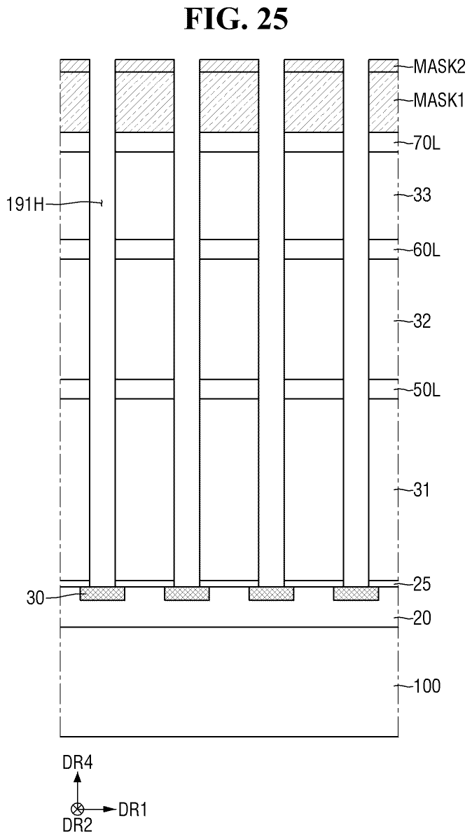

Referring to FIGS. 24 and 25, the third mask film MASK3 on the second mask film MASK2 may be removed to expose the upper face of the second mask film MASK2.

In an embodiment, the upper face of the second mask film MASK2 may be exposed while the lower electrode hole 191H is being formed.

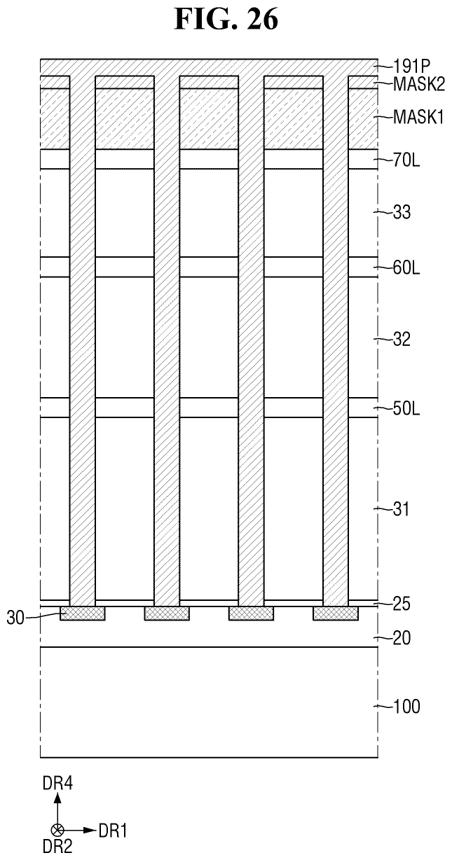

Referring to FIGS. 25 and 26, the lower electrode film 191P may be formed on the conductive pattern 30.

The lower electrode film 191P may be formed in the lower electrode hole 191H. The lower electrode film 191P may be formed on the upper face of the second mask film MASK2.

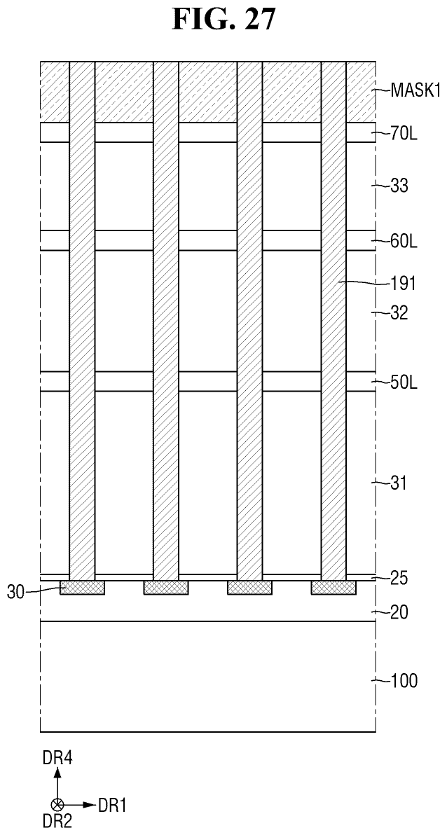

Referring to FIGS. 26 and 27, the lower electrode 191 may be formed by removing the lower electrode film 191P on the upper face of the second mask film MASK2, and the second mask film MASK2.

Since the second mask film MASK2 includes or is formed of the same material as the lower electrode film 191P, a part of the second mask film MASK2 and the lower electrode film 191P may be removed at the same time. The upper face of the first mask film MASK1 may be exposed, accordingly.

The lower electrode 191 may be formed in the first to third electrode support films 50L, 60L, and 70L and the first to third mold insulating films 31, 32, and 33. The lower electrode 191 may be formed in the first mask film MASK1.

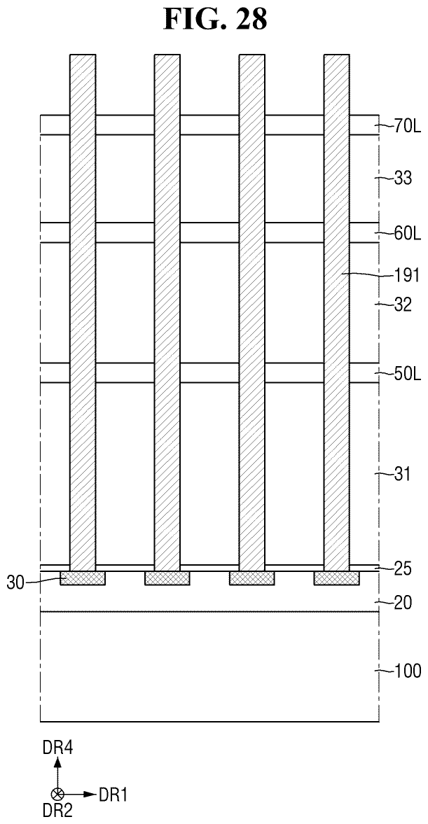

Referring to FIGS. 27 and 28, the first mask film MASK1 on the third electrode support film 70L may be removed.

The upper face of the third electrode support film 70L may be exposed. When the first mask film MASK1 is removed, a part of the lower electrode 191 may protrude beyond the third electrode support film 70L in the fourth direction DR4.

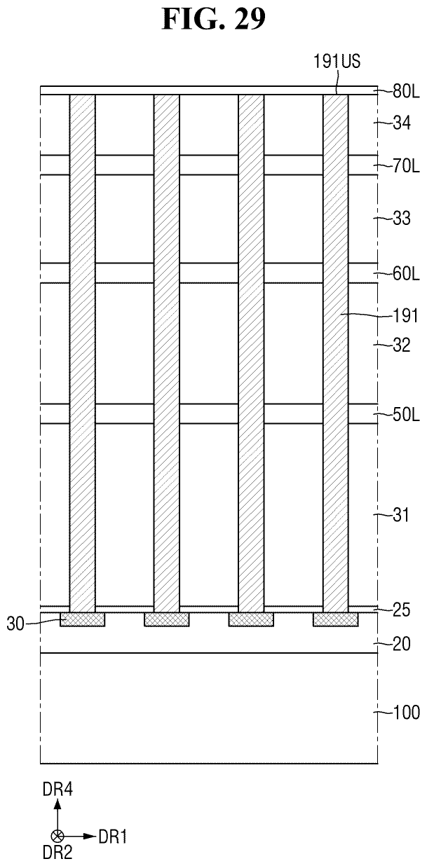

Referring to FIGS. 28 and 29, a fourth mold insulating film 34 may be formed on the third electrode support film 70L.

The fourth mold insulating film 34 may wrap the side walls of the lower electrode 191 that protrudes beyond the third electrode support film 70L. The fourth mold insulating film 34 does not cover the upper face 191US of the lower electrode.

Subsequently, an electrode capping support film 80L may be formed on the fourth mold insulating film 34 and the lower electrode 191. The electrode capping support film 80L may be in contact with the upper face 191US of the lower electrode.

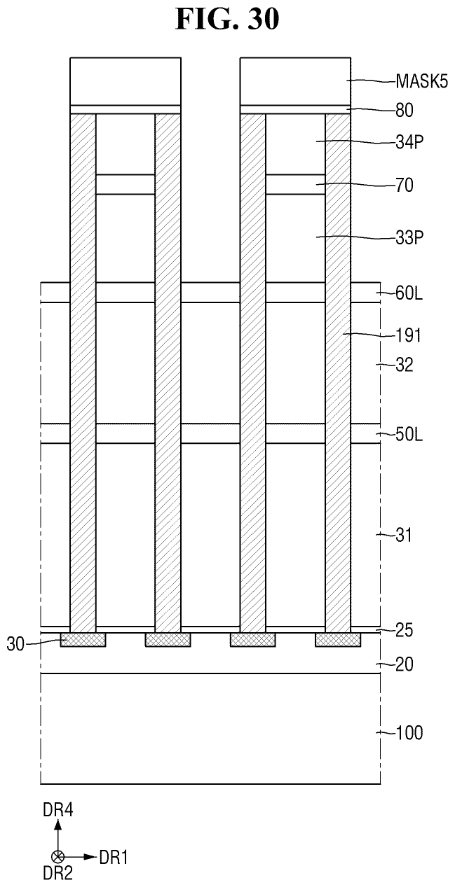

Referring to FIGS. 29 and 30, a fifth mask film MASK5 may be formed on the electrode capping support film 80L.

Subsequently, the electrode capping support film 80L, the fourth mold insulating film 34, the third electrode support film 70L, and the third mold insulating film 33 may be patterned, by using the fifth mask film MASK5 as an etching mask.

The electrode capping support 80 may be formed by patterning the electrode capping support film 80L. The third electrode side wall support 70 may be formed by patterning the third electrode support film 70L.

The fourth mold insulating film 34 may be patterned to form a fourth mold insulating pattern 34P between the electrode capping support 80 and the third electrode side wall support 70. The third mold insulating film 33 may be patterned to form a third mold insulating pattern 33P between the third electrode side wall support 70 and the second electrode support film 60L.

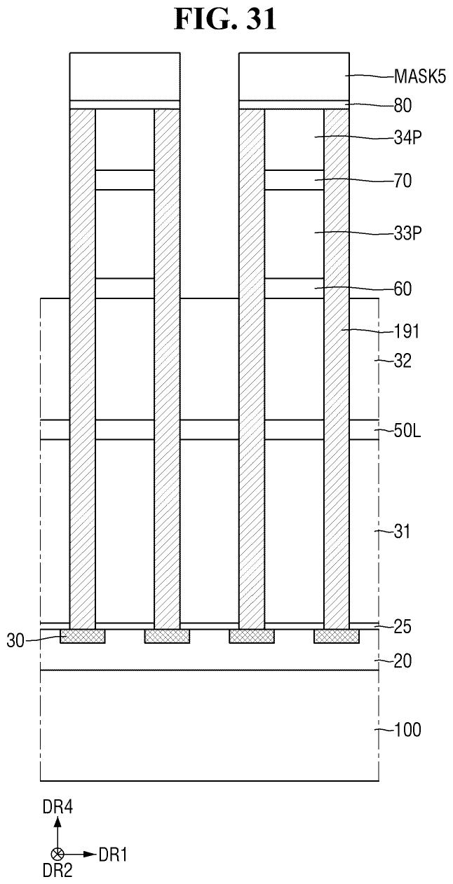

Referring to FIGS. 30 and 31, the second electrode support film 60L may be patterned, by using the fifth mask film MASK5 as an etching mask.

The second electrode side wall support 60 may be formed by patterning the second electrode support film 60L. The second mold insulating film 32 may be exposed, accordingly.

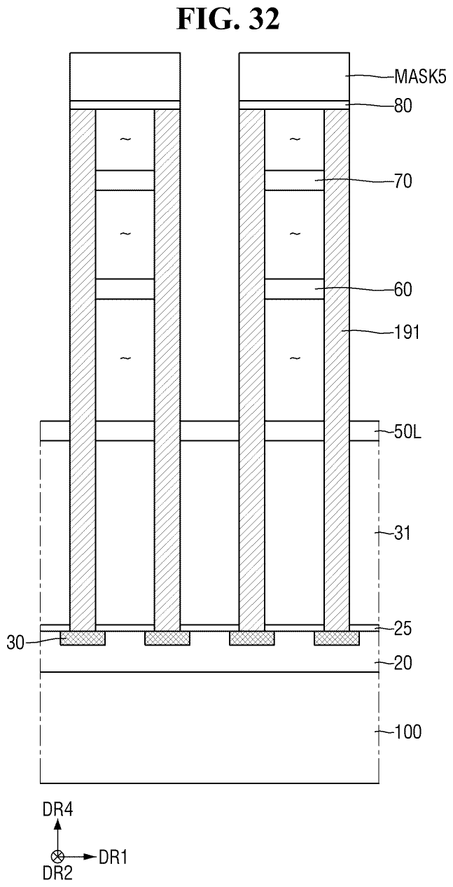

Referring to FIGS. 31 and 32, the second mold insulating film 32 may be removed, using wet etching.

The second mold insulating film 32 may be removed to expose the first electrode support film 50L. While the second mold insulating film 32 is being removed, the fourth mold insulating pattern 34P between the electrode capping support 80 and the third electrode side wall support 70 may be removed. While the second mold insulating film 32 is being removed, the third mold insulating pattern 33P between the third electrode side wall support 70 and the second electrode side wall support 60 may be removed.

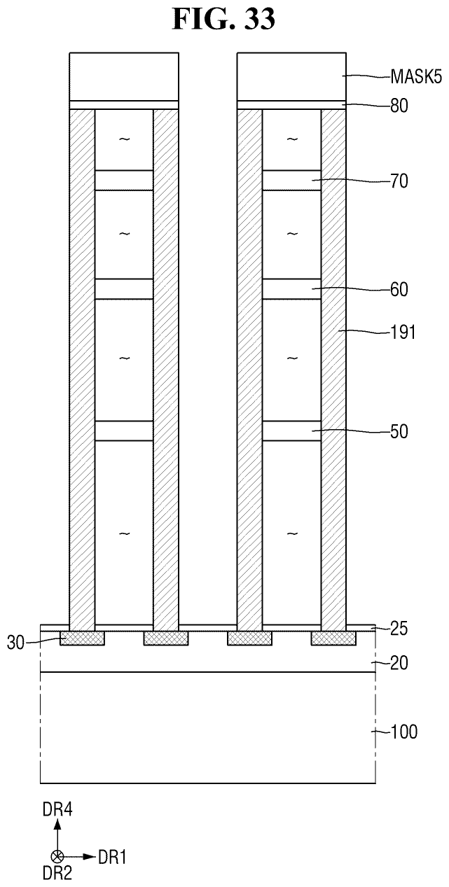

Referring to FIGS. 32 and 33, the first electrode support film 50L may be patterned, by using the fifth mask film MASK5 as an etching mask.

The first electrode side wall support 50 may be formed by patterning the first electrode support film 50L. During the formation of the first electrode side wall support 50, the first mold insulating film 31 may be exposed, and then the first mold insulating film 31 may be removed, using wet etching.

The fifth mask film MASK5 may be removed.

Next, referring to FIG. 1, the capacitor dielectric film 192 and the upper electrode 193 may be formed.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor memory device comprising:
a conductive pattern on a substrate;
a lower electrode which is connected to the conductive pattern, extends in a first direction perpendicular to an upper surface of the substrate, and includes a first portion and a second portion, the first portion of the lower electrode being disposed between the conductive pattern and the second portion of the lower electrode;
one or more electrode side wall supports that support the lower electrode and are in contact with a side wall of the lower electrode;
an electrode capping support which is disposed on the lower electrode, and is in contact with an upper face of the lower electrode;
a capacitor dielectric film on the lower electrode, the electrode side wall support, and the electrode capping support; and
an upper electrode on the capacitor dielectric film,
wherein the first portion of the lower electrode has an increasing width in the first direction away from the conductive pattern, a width of the first portion of the lower electrode being measured in a second direction parallel to the upper surface of the substrate, and
wherein a slope of the side wall of the first portion of the lower electrode is different from a slope of the side wall of the second portion of the lower electrode.

2. The semiconductor memory device of claim 1,
wherein the one or more electrode side wall supports are in contact with the side wall of the first portion of the lower electrode, and
wherein an uppermost surface of the one or more electrode side wall supports is coplanar with a boundary between the first portion and the second portion of the lower electrode.

3. The semiconductor memory device of claim 1,
wherein the one or more electrode side wall supports include an uppermost electrode side wall support that is farthest away from the conductive pattern,
the uppermost electrode side wall support includes an upper surface and a bottom surface that are opposite to each other in the first direction,
the bottom surface of the uppermost electrode side wall support is adjacent to the conductive pattern,
the first portion of the lower electrode and the second portion of the lower electrode are directly connected, and
a boundary between the first portion of the lower electrode and the second portion of the lower electrode is located at the same height level as the upper surface of the uppermost electrode side wall support.

4. The semiconductor memory device of claim 1,
wherein the one or more electrode side wall supports include an uppermost electrode side wall support that is farthest away from the conductive pattern,
the uppermost electrode side wall support is spaced apart from the electrode capping support in the first direction, and
a part of the side wall of the first portion of the lower electrode and a part of the side wall of the second portion of the lower electrode are in contact with the uppermost electrode side wall support.

5. The semiconductor memory device of claim 1,
wherein the electrode capping support covers a part of the side wall of the second portion of the lower electrode.

6. The semiconductor memory device of claim 1,
wherein a width of an upper surface of the first portion of the lower electrode is greater than a width of a lower surface of the second portion of the lower electrode.

7. The semiconductor memory device of claim 6,
wherein the lower electrode includes a third portion disposed between the first portion of the lower electrode and the second portion of the lower electrode, and
a side wall of the third portion of the lower electrode has a rounded shape.

8. The semiconductor memory device of claim 1,
wherein a width of an upper surface of the first portion of the lower electrode is smaller than a width of a lower surface of the second portion of the lower electrode.

9. The semiconductor memory device of claim 8,
wherein the lower electrode includes a third portion disposed between the first portion of the lower electrode and the second portion of the lower electrode, and
the side wall of the third portion of the lower electrode has a rounded shape.

10. The semiconductor memory device of claim 1,
wherein a width of an upper surface of the first portion of the lower electrode is the same as a width of a lower surface of the second portion of the lower electrode.

11. A semiconductor memory device comprising:
a conductive pattern on a substrate;
a lower electrode which is connected to the conductive pattern, extends in a first direction perpendicular to an upper surface of the substrate, and includes a first portion and a second portion, the first portion of the lower electrode being disposed between the conductive pattern and the second portion of the lower electrode;
a plurality of electrode side wall supports that support the lower electrode and are in contact with a side wall of the lower electrode;
a capacitor dielectric film on the lower electrode and each of the plurality of electrode side wall supports; and
an upper electrode on the capacitor dielectric film,
wherein the first portion of the lower electrode has an increasing width in the first direction away from the conductive pattern, a width of the first portion of the lower electrode being measured in a second direction parallel to the upper surface of the substrate,
wherein a slope of the side wall of the first portion of the lower electrode is different from a slope of the side wall of the second portion of the lower electrode,
wherein the plurality of electrode side wall supports include an uppermost electrode side wall support that is farthest away from the conductive pattern in the first direction,
wherein the uppermost electrode side wall support includes a bottom surface that is adjacent to the conductive pattern and an upper surface opposite to the bottom surface of the uppermost electrode side wall support in the first direction, and
wherein a part of the first portion of the lower electrode protrudes in the first direction beyond the upper surface of the uppermost electrode side wall support.

12. The semiconductor memory device of claim 11, further comprising:
an electrode capping support which is disposed on the lower electrode and is in contact with an upper surface of the lower electrode.

13. The semiconductor memory device of claim 12,
wherein the electrode capping support covers a part of a side wall of the second portion of the lower electrode.

14. The semiconductor memory device of claim 11,
wherein a width of an upper surface of the first portion of the lower electrode is greater than a width of a lower surface of the second portion of the lower electrode.

15. The semiconductor memory device of claim 14,
wherein the lower electrode includes a third portion disposed between the first portion of the lower electrode and the second portion of the lower electrode, and
a side wall of the third portion of the lower electrode has a rounded shape.

16. The semiconductor memory device of claim 11,
wherein a width of an upper surface of the first portion of the lower electrode is smaller than a width of a lower surface of the second portion of the lower electrode.

17. The semiconductor memory device of claim 16,
wherein the lower electrode includes a third portion disposed between the first portion of the lower electrode and the second portion of the lower electrode, and
the side wall of the third portion of the lower electrode has a rounded shape.

18. A semiconductor memory device comprising:
a substrate which includes an active region defined by an element separation film and extending in a first direction, the active region including a first portion and a pair of second portions disposed on opposite sides of the first portion and the first direction being parallel to an upper surface of the substrate;
a word line which extends in a second direction parallel to the upper surface of the substrate and different from the first direction, is buried in the substrate and the element separation film, and is disposed between the first portion of the active region and one of the pair of second portions of the active region;
a bit line contact connected to the first portion of the active region;
a bit line which is connected to the bit line contact and extends in a third direction different from the first direction and the second direction and is disposed on the bit line contact;
a landing pad connected to the second portion of the active region; and
a capacitor connected to the landing pad and disposed on the landing pad,
wherein the capacitor includes a lower electrode connected to the landing pad and extending in the third direction, a plurality of electrode side wall supports which support the lower electrode and are in contact with a side wall of the lower electrode,
an electrode capping support which is disposed on the lower electrode and is in contact with an upper face of the lower electrode,
a capacitor dielectric film on the lower electrode, each of the plurality of electrode side wall supports, and the electrode capping support, and
an upper electrode on the capacitor dielectric film,
wherein the lower electrode includes a first portion of the lower electrode and a second portion of the lower electrode,
wherein the first portion of the lower electrode has an increasing width in the third direction away from the landing pad,
wherein the electrode capping support is in contact with the second portion of the lower electrode, and
wherein a slope of the side wall of the first portion of the lower electrode is different from a slope of the side wall of the second portion of the lower electrode.

19. The semiconductor memory device of claim 18,
wherein the electrode side wall supports include an uppermost electrode side wall support that is farthest away from the landing pad in the third direction,
wherein the uppermost electrode side wall support includes a bottom surface that is adjacent to the landing pad, and an upper surface opposite to the bottom surface of the uppermost electrode side wall support,
wherein the upper electrode side wall support is in contact with the side wall of the first portion of the lower electrode, and
wherein a part of the first portion of the lower electrode protrudes beyond the upper surface of the uppermost electrode side wall support in the third direction.

20. The semiconductor memory device of claim 18,
wherein a width of an upper surface of the first portion of the lower electrode is different from a width of a lower surface of the second portion of the lower electrode.
